(19) United States
(12) Patent Application Publication
(10) Pub. No.: US 2025/0374730 A1
(43) Pub. Date: Dec. 4, 2025

(54) DISPLAY PANEL AND DISPLAY DEVICE INCLUDING THE SAME

(71) Applicant: LG DISPLAY CO., LTD., Seoul (KR)

(72) Inventor: Kyoung June JUNG, Paju-si (KR)

(73) Assignee: LG DISPLAY CO., LTD., Seoul (KR)

(21) Appl. No.: 19/225,526

(22) Filed: Jun. 2, 2025

(30) Foreign Application Priority Data
Jun. 4, 2024 (KR) 10-2024-0073002

(51) Int. Cl. H10H 29/34; H10H 29/37

(52) U.S. Cl. CPC H10H 29/345; H10H 29/37

(57) ABSTRACT

A display panel and a display device including the same are disclosed. A display panel according to the present specification may include a first light-emitting element having a first size and implementing a first color, a second light-emitting element having a second size different from the first size and implementing a second color, a third light-emitting element having a third size different from the first size and implementing a third color, and a trench formed between the second light-emitting element and the third light-emitting element. According to the present specification, a design margin of a display device may be secured.

### CROSS-REFERENCE TO RELATED APPLICATION

This application claims priority to and the benefit of Korean Patent Application No. 10-2024-0073002, filed on Jun. 4, 2024, the disclosure of which is incorporated herein by reference in its entirety.

### BACKGROUND

### 1. Field of the Disclosure

The present specification relates to a display panel and a display device including the same.

### 2. Discussion of Related Art

Display devices are being applied to various electronic devices such as TVs, mobile phones, laptops, and tablets.

Display devices include organic light-emitting display (OLED) devices, which are self-emissive, liquid crystal display (LCD) devices, which require a separate light source, and the like.

In recent years, display devices including light-emitting diodes (LEDs) have been gaining attention as next-generation display devices. Since LEDs are formed of inorganic materials rather than organic materials, the display devices including LEDs have a fast lighting speed and high luminous efficiency, and can display high-brightness images compared to liquid crystal display devices and organic light-emitting display devices.

Moisture and the like may penetrate into a display device including an inorganic light-emitting element from the outside. When external particles, such as penetrating moisture, accumulate inside the display device, technical issues, such as reduced reliability, may occur, and thus measures are required to address this issue.

### SUMMARY

As described above, external particles such as moisture may penetrate a display device including an inorganic light-emitting element (e.g., a micro light-emitting diode (micro LED)), which may reduce the reliability of the display device.

Therefore, the present specification is directed to providing a display panel with improved operational reliability and a display device including the same.

Objectives according to embodiments of the present specification are not limited to the above-described objectives, and other objectives that are not described herein will be apparently understood by those skilled in the art from the following description.

According to an aspect of the present disclosure, there is provided a display panel including a first light-emitting element having a first size and implementing a first color, a second light-emitting element having a second size different from the first size and implementing a second color, a third light-emitting element having a third size different from the first size and implementing a third color, and a trench formed between the second light-emitting element and the third light-emitting element.

According to another aspect of the present disclosure, there is provided a display device including a display panel having a plurality of pixels, and a bending area disposed in a first direction from the display panel, wherein each of the plurality of pixels includes a plurality of light-emitting elements, the plurality of light-emitting elements include a plurality of first light-emitting elements each having a first size and implementing a first color, a plurality of second light-emitting elements each having a second size different from the first size and implementing a second color, and a plurality of third light-emitting elements each having a third size different from the first size and implementing a third color, and the display panel includes a first trench disposed between the second light-emitting elements and the third light-emitting elements and a second trench disposed between the plurality of light-emitting elements.

Specific details according to various examples of the present specification other than the means for solving the above-mentioned problems are included in the description and drawings below.

### BRIEF DESCRIPTION OF THE DRAWINGS

The accompanying drawings, which are included to provide a further understanding of the present disclosure and are incorporated in and constitute a part of this application, illustrate example embodiments of the disclosure and together with the description serve to explain the principles of the disclosure. In the drawings:

FIG. 1 is an exploded perspective view of a display device according to an example embodiment of the present specification;

FIG. 2 is a plan view illustrating the display device according to an example embodiment of the present specification;

FIG. 3 is a plan view illustrating the display device according to an example embodiment of the present specification;

FIG. 4 is a plan view illustrating the display device according to an example embodiment of the present specification;

FIG. 5 is a plan view illustrating the display device according to an example embodiment of the present specification;

FIG. 6 is a plan view illustrating the display device according to an example embodiment of the present specification;

FIGS. 7 and 8 are plan views illustrating a display device according to an example embodiment of the present specification;

FIGS. 9 and 10 are plan views illustrating a display device according to a comparative example;

FIGS. 11 to 13 are plan views illustrating display devices according to modified example embodiments of the present specification;

FIG. 14 is a plan view illustrating a display device according to an example embodiment of the present specification;

FIG. 15 is a plan view illustrating a display device according to a comparative example;

FIGS. 16 and 17 are plan views illustrating display devices according to modified example embodiments of the present specification;

FIG. 18 is a plan view illustrating a display device according to an example embodiment of the present specification;

FIG. 19 is an enlarged view illustrating the display device according to an example embodiment of the present specification;

FIG. 20 is a diagram illustrating a circuit structure according to an example embodiment of the present specification;

FIG. 21 is a cross-sectional view illustrating the display device according to an example embodiment of the present specification;

FIG. 22 is a cross-sectional view illustrating the display device according to an example embodiment of the present specification;

FIG. 23 is a cross-sectional view illustrating the display device according to an example embodiment of the present specification;

FIGS. 24 and 25 are cross-sectional views illustrating a display device according to an example embodiment of the present specification;

FIGS. 26 and 27 are cross-sectional views illustrating a display device according to a comparative example;

FIGS. 28 and 29 are cross-sectional views illustrating the display devices according to an example embodiment of the present specification;

FIG. 30 is a cross-sectional view illustrating a display device according to an example embodiment of the present specification;

FIG. 31 is a cross-sectional view illustrating the display device according to an example embodiment of the present specification;

FIG. 32 is a view illustrating a device to which the display device according to example embodiments of the present specification is applied;

FIG. 33 is a view illustrating a device to which the display device according to example embodiments of the present specification is applied;

FIG. 34 is a view illustrating a device to which the display device according to example embodiments of the present specification is applied; and

FIG. 35 is a view illustrating a device to which the display device according to example embodiments of the present specification is applied.

### DETAILED DESCRIPTION

Advantages and features of the present specification and a method of achieving the same should become clear with embodiments described in detail below with reference to the accompanying drawings. However, the present specification is not limited to the embodiments described below and may be implemented with a variety of different modifications. The embodiments are merely provided to allow those skilled in the art to completely understand the scope of the present specification.

The shapes, dimensions, ratios, angles, numbers, and the like disclosed in the drawings for describing the embodiments of the present specification are merely illustrative and are not limited to matters shown in the present specification. Like reference numerals refer to like elements throughout the specification. Further, in describing the present specification, detailed descriptions of well-known technologies will be omitted when it is determined that they may unnecessarily obscure the features of the present specification. Terms such as “including,” “having,” and “comprising” used herein are intended to allow other elements to be added unless the terms are used with the term “only.” Any references to the singular may include the plural unless expressly stated otherwise.

Components are interpreted as including an ordinary error range even if no such margin is explicitly stated.

In the case of a description of a positional relationship, for example, in the case in which a position relationship between two portions is described with the terms “on,” “above,” “under,” “next to,” or the like, one or more portions may be interposed therebetween unless the term, for example, “right”, “directly”, or “near” is used in the expression.

For the description of a temporal relationship, when a temporal relationship is described as “after,” “subsequently to,” “next,” “before,” and the like, a non-consecutive case may be included unless the term “immediately” or “directly” is used in the expression.

Although the terms “first,” “second,” and the like may be used herein to describe various components, the components are not limited by the terms. These terms are used only to refer to one component separately from another. Therefore, a first component described below may be a second component within the technological scope of the present specification.

Terms such as first, second, A, B, (a), (b), or the like may be used herein when describing components of the present specification. Such terms are used only to refer to a component separately from another component, but do not limit the nature, sequence, order, number, or the like of components.

It is to be understood that when a component is described as being “connected,” “coupled,” “linked,” or “attached” to another component, the component may be directly connected, coupled, linked, or attached to the other component, but, unless specifically stated otherwise, still another component may be interposed between these two components so that they are indirectly connected, coupled, linked, or attached.

It is also to be understood that when a component or layer is described as being “overlapping” another component or layer, the component or layer may be in direct contact with or directly overlapping the other component or layer, but, unless specifically stated otherwise, still another component or layer may be interposed between these two components or layers so that they are indirectly overlapping each other.

The term “at least one” should be understood as including any and all combinations of one or more of the associated listed components. For example, the meaning of “at least one of a first component, a second component, and a third component” denotes the combination of all components proposed from two or more of the first component, the second component, and the third component as well as the first component, the second component, or the third component.

The terms “first direction,” “second direction,” “third direction,” “X-axis direction,” “Y-axis direction,” and “Z-axis direction” should not be interpreted as referring only to geometrical relationships that are perpendicular to each other, but may indicate a broader range of directions within the functional scope of the configuration described in the present specification.

The features of various embodiments of the present specification may be partially or entirely combined with each other. The embodiments may be technically linked and operate in various ways and may be carried out independently of or in association with each other.

Hereinafter, various embodiments of the present specification will be described in detail with reference to the accompanying drawings.

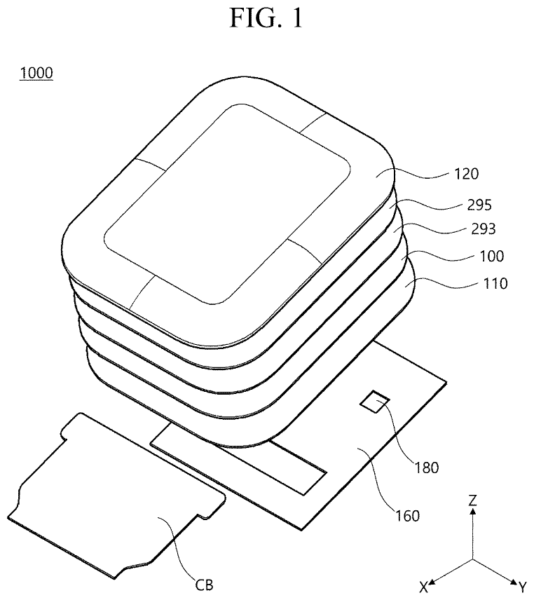

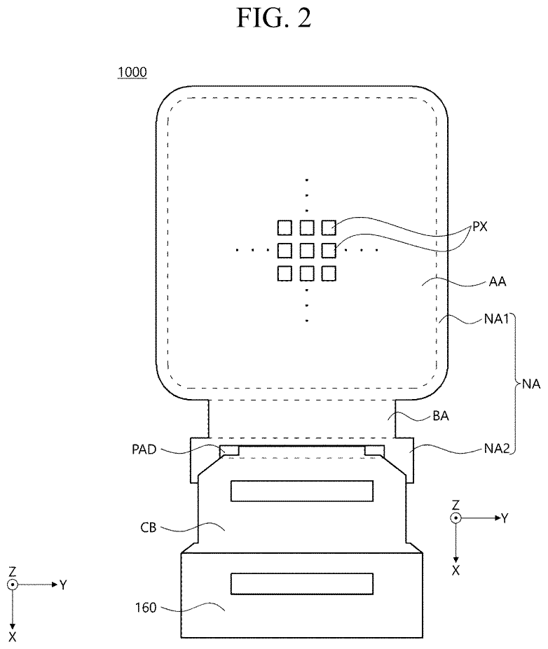

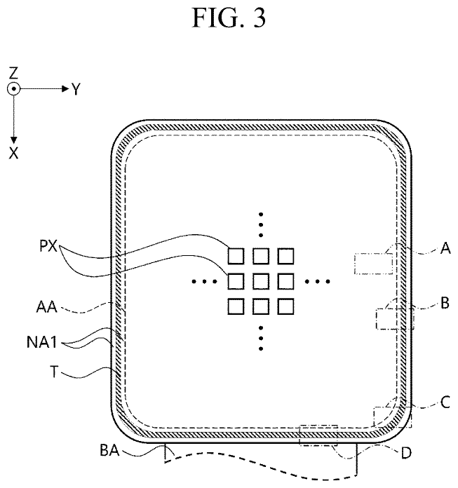

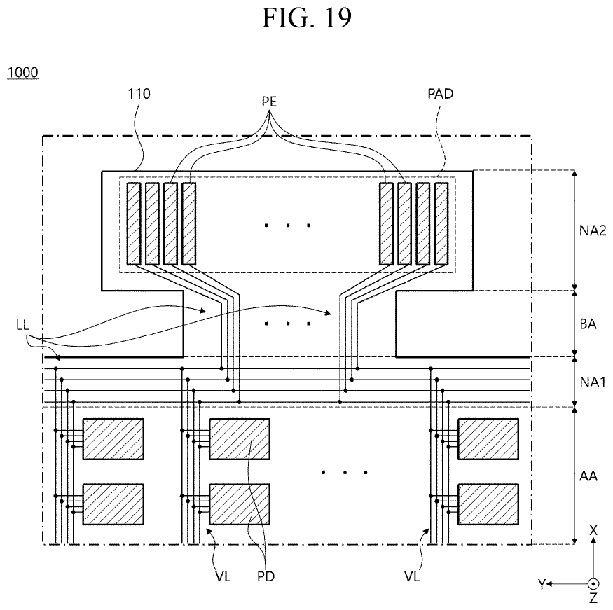

FIG. 1 is an exploded perspective view illustrating a display device according to an example embodiment of the present specification. FIG. 2 is a plan view illustrating the display device according to an example embodiment of the present specification. FIG. 3 is a plan view illustrating the display device according to an example embodiment of the present specification. FIG. 19 is an enlarged view illustrating the display device according to an example embodiment of the present specification.

As shown in FIGS. 1, 2, and 19, a display device 1000 according to an example embodiment of the present specification may include a display panel 100, a polarizing layer 293, a second adhesive layer 295, a cover member 120, a support substrate 110, a flexible circuit board CB, and a printed circuit board 160.

For example, the display device 1000 may include a substrate 110. The substrate 110 may be a member that supports other components of the display device 1000. The substrate 110 may be formed of an insulating material. For example, the substrate 110 may be formed of glass, resin, or the like. In addition, the substrate 110 may be formed of a material that has flexibility. For example, the substrate 110 may be formed of a plastic material having flexibility, such as a polyimide (PI). However, the embodiments of the present specification are not limited thereto.

The display panel 100 may implement information, videos, and/or images provided to a user. For example, the display panel 100 may include a display area AA and a non-display area NA. For example, the substrate 110 may include a display area AA and a non-display area NA. The display area AA and the non-display area NA are not limited to the substrate 110 but may be described throughout the entire display device 1000.

The display area AA may be an area in which an image is displayed. The display area AA may include a plurality of pixels PX. Each of the plurality of pixels PX may be composed of a plurality of sub-pixels. A plurality of light-emitting elements may be disposed in each of the plurality of sub-pixels. The plurality of light-emitting elements may be configured differently depending on the type of the display device 1000. For example, when the display device 1000 is an inorganic light-emitting display device, the light-emitting element may be a light-emitting diode (LED), a micro light-emitting diode (micro LED), or a mini light-emitting diode (mini LED), but the embodiments of the present specification are not limited thereto.

The non-display area NA may be an area in which an image is not displayed. Various lines, circuits, and the like for driving the plurality of pixels PX of the display area AA may be disposed in the non-display area NA. For example, in the non-display area NA, various lines and driving circuits may be mounted, and a pad part PAD to which an integrated circuit, a printed circuit, or the like is connected may be disposed, but the embodiments of the present specification are not limited thereto.

For example, the driving circuits may be data driving circuits and/or gate driving circuits, but the embodiments of the present specification are not limited thereto. Lines through which control signals for controlling the driving circuits are supplied may be disposed on the display panel 100. For example, the control signals may include various timing signals such as clock signals, input data enable signals, and synchronization signals, but the embodiments of the present specification are not limited thereto. The control signals may be received through the pad part PAD. For example, link lines LL for transmitting signals may be disposed in the non-display area NA. For example, driving components such as the flexible circuit board CB and the printed circuit board 160 may be connected to the pad part PAD.

According to the present specification, the non-display area NA may include a first non-display area NA1, a bending area BA, and a second non-display area NA2. For example, the first non-display area NA1 may be an area surrounding at least a portion of the display area AA. The bending area BA may be an area extending from at least one of a plurality of sides of the first non-display area NA1, and may be a bendable area. The bending area BA may be disposed in the first direction from the display panel 100. The second non-display area NA2 may be an area extending from the bending area BA, and the pad part PAD may be disposed therein. For example, the bending area BA may be in a bent state, and the remaining area of the substrate 110, excluding the bending area BA, may be in a flat state. In this case, as the bending area BA is bent, the second non-display area NA2 may be located on a rear surface of the display area AA. However, the embodiments of the present specification are not limited thereto.

As shown in FIG. 3, the first non-display area NA1 may include an area in which a trench T is disposed. The area in which the trench Tis disposed may be formed to be substantially the same as the shape of the first non-display area NA1. For example, the first non-display area NA1 may have a rectangular shape with four rounded corners, as will be described below. In this case, the area in which the trench T is disposed may have a rectangular shape with four rounded corners. The rectangular shape formed by the outermost perimeter of the area in which the trench T is disposed may have a smaller area than the rectangular shape formed by the outermost perimeter of the first non-display area NA1. The area in which the trench T is formed may be disposed to surround the plurality of pixels PX.

In one embodiment, the display area AA may include an area in which the trench T is formed. The area in which the trench T is formed may be disposed to surround the plurality of pixels PX.

The trench T may be disposed to surround the plurality of pixels PX. At least a portion of the trench T may be disposed between the plurality of light-emitting elements. The plurality of light-emitting elements may be disposed in the display area AA and/or the first non-display area NA1. The trench T may be disposed between the display area AA and the bending area BA. The trench T may be disposed between the display panel 100 and the bending area BA. The trench T may be disposed between at least a portion of the display panel 100 and the bending area BA.

The display area AA of the substrate 110 or the display device 1000 may be configured in various shapes depending on the design of the display device 1000. For example, the display area AA may be configured in a rectangular shape with four rounded corners, but the embodiments of the present specification are not limited thereto. For another example, the display area AA may be configured in a rectangular shape with four right-angled corners, a circular shape, or the like, but the embodiments of the present specification are not limited thereto.

According to the present specification, a width of the second non-display area NA2, in which a plurality of pad electrodes PE are disposed, may be greater than a width of the bending area BA, in which only the plurality of link lines LL are disposed. A width of the display area AA in which the plurality of sub-pixels are disposed may be greater than the width of the bending area BA in which only the plurality of link lines LL are disposed. In the drawings, the width of the bending area BA is illustrated as being less than that of each of the other areas of the substrate 110, but the shape of the substrate 110 including the bending area BA is an example, and the embodiments of the present specification are not limited thereto.

As shown in FIG. 19, a plurality of pixel driving circuits PD may be disposed in the display area AA. The plurality of pixel driving circuits PD may be circuits for driving the light-emitting elements of the plurality of sub-pixels. Each of the plurality of pixel driving circuits PD includes a plurality of transistors, including driving transistors, and a storage capacitor, and the like, and the pixel driving circuits PD may supply control signals, power, and driving current to the light-emitting elements of the plurality of sub-pixels, thereby controlling the light-emission operations of the plurality of light-emitting elements. For example, the pixel driving circuit PD may include power lines and signal lines for controlling an on/off state and/or a light-emission time of the light-emitting element. For example, the plurality of pixel driving circuits PD may be driving drivers fabricated using a metal-oxide-semiconductor field-effect transistor (MOSFET) manufacturing process on a semiconductor substrate, but the embodiments of the present specification are not limited thereto. The driving drivers include the plurality of pixel driving circuits PD, and may drive the plurality of sub-pixels.

As shown in FIG. 1 together, the flexible circuit board CB and the printed circuit board 160 may be disposed below the display panel 100. The flexible circuit board CB and the printed circuit board 160 may be disposed at at least one side edge of the display panel 100, but the embodiments of the present specification are not limited thereto. One side of the flexible circuit board CB may be attached to the display panel 100, and the other side thereof may be attached to the printed circuit board 160, but the embodiments of the present specification are not limited thereto. The flexible circuit board CB may be a flexible film, but the embodiments of the present specification are not limited thereto.

The pad part PAD including the plurality of pad electrodes PE may be disposed in the second non-display area NA2. The driving components, including one or more flexible circuit boards (or flexible films) CB and the printed circuit board 160, may be attached or bonded to the pad part PAD. The plurality of pad electrodes PE of the pad part PAD are electrically connected to one or more flexible circuit boards (or flexible films) CB and may transmit various signals (or power) output from the printed circuit board 160 and the flexible circuit boards (or flexible films) CB to the plurality of pixel driving circuits PD in the display area AA.

The flexible circuit board (or flexible film) CB may be a film in which various components are disposed on a base film having flexibility. For example, a driving integrated circuit (IC), such as a gate driver IC or a data driver IC, may be disposed on the flexible circuit board (or flexible film) CB, but the embodiments of the present specification are not limited thereto. The driving IC may be a component that processes data and driving signals for displaying images. The driving IC may be disposed using methods, such as chip on glass (COG), chip on film (COF), or tape carrier package (TCP), depending on a mounting method, but the embodiments of the present specification are not limited thereto. The flexible circuit board (or flexible film) CB may be attached or bonded onto the plurality of pad electrodes PE through a conductive adhesive layer, but the embodiments of the present specification are not limited thereto.

The printed circuit board 160 may be a component that is electrically connected to one or more flexible circuit boards (or flexible films) CB and supplies signals to the driving IC. The printed circuit board 160 is disposed on one side of the flexible circuit board (or flexible film) CB, and may be electrically connected to the flexible circuit board (or flexible film) CB. Various components for supplying various signals to the driving IC may be disposed on the printed circuit board 160. For example, various components, such as a timing controller, a power supply part, a memory, or a processor, may be disposed on the printed circuit board 160. For example, the printed circuit board 160 may include a power management integrated circuit (PMIC), but the embodiments of the present specification are not limited thereto.

The printed circuit board 160 may include at least one hole 180, but the embodiments of the present specification are not limited thereto. An internal component configured to detect ambient light or temperature, which may be provided to a plurality of sensors, may be disposed in an area corresponding to the at least one hole 180. For example, the internal component may include an ambient light sensor (ALS), a temperature sensor, or the like, but the embodiments of the present specification are not limited thereto. For example, the hole 180 may be a through hole or the like, but the embodiments of the present specification are not limited thereto.

As shown in FIG. 1, the polarizing layer 293 may be disposed on the display panel 100. The polarizing layer 293 may prevent or reduce the light generated from an external light source from entering the display panel 100 and affecting the light-emitting elements or the like.

The cover member 120 may be disposed on the polarizing layer 293. The cover member 120 may be a member for protecting the display panel 100. The second adhesive layer 295 may be disposed between the polarizing layer 293 and the cover member 120. The cover member 120 may be attached to the display panel 100 by the second adhesive layer 295. The second adhesive layer 295 may include an optically clear adhesive (OCA), an optically clear resin (OCR), a pressure-sensitive adhesive (PSA), or the like, but the embodiments of the present specification are not limited thereto.

The support substrate 110 may be disposed between the display panel 100 and the printed circuit board 160. The support substrate 110 may reinforce the rigidity of the display panel 100. The support substrate 110 may be a back plate, but the embodiments of the present specification are not limited thereto.

As shown in FIGS. 1, 2, and 19, a plurality of link lines LL may be disposed in the non-display area NA. The plurality of link lines LL may be lines that transmit various signals supplied from one or more flexible circuit boards (or flexible films) CB and the printed circuit board 160 to the display area AA. The plurality of link lines LL may extend from the plurality of pad electrodes PE in the second non-display area NA2 toward the bending area BA and the first non-display area NA1 and may be electrically connected to a plurality of driving lines VL in the display area AA. The plurality of pixel driving circuits PD may be driven by receiving signals from one or more flexible circuit boards (or flexible films) CB and the printed circuit board 160 through the driving lines VL in the display area AA and the link lines LL in the non-display area NA.

For example, the plurality of driving lines VL, along with the plurality of link lines LL, may serve as lines for transmitting signals output from the flexible circuit board (or flexible film) CB and the printed circuit board 160 to the plurality of pixel driving circuits PD. The plurality of driving lines VL may be disposed in the display area AA and electrically connected to the plurality of pixel driving circuits PD, respectively. The plurality of driving lines VL may extend from the display area AA toward the non-display area NA to be electrically connected to the plurality of link lines LL. Accordingly, the signals output from the flexible circuit board (or flexible film) CB and the printed circuit board 160 may be transmitted to each of the plurality of pixel driving circuits PD through the plurality of link lines LL and the plurality of driving lines VL.

As the bending area BA is bent, some of the plurality of link lines LL may also be bent. Stress may be concentrated on a portion of the bent link lines LL, and as a result, cracks may occur in the link lines LL. Accordingly, the plurality of link lines LL may be formed of a conductive material with excellent flexibility to reduce cracks during the bending of the bending area BA. For example, the plurality of link lines LL may be formed of a conductive material with excellent flexibility, such as gold (Au), silver (Ag), or aluminum (Al), but the embodiments of the present specification are not limited thereto. In addition, the plurality of link lines LL may be formed of one of various conductive materials used in the display area AA. For example, the plurality of link lines LL may be formed of molybdenum (Mo), chromium (Cr), titanium (Ti), nickel (Ni), neodymium (Nd), copper (Cu), an alloy of silver (Ag) and magnesium (Mg), or alloys thereof, but the embodiments of the present specification are not limited thereto. The plurality of link lines LL may be configured in a multilayer structure including various conductive materials. For example, the plurality of link lines LL may be configured in a triple-layer structure of titanium (Ti)/aluminum (Al)/titanium (Ti), but the embodiments of the present specification are not limited thereto.

The plurality of link lines LL may be configured in various shapes to reduce stress. At least some of the plurality of link lines LL disposed in the bending area BA may extend in the same direction as an extension direction of the bending area BA, or extend in a direction different from the extension direction of the bending area BA to reduce stress. For example, when the bending area BA extends in one direction from the first non-display area NA1 toward the second non-display area NA2, at least some of the link lines LL disposed in the bending area BA may extend in a direction oblique to the one direction. For another example, at least some of the plurality of link lines LL may be configured in various pattern shapes. For example, at least some of the plurality of link lines LL disposed in the bending area BA may have a conductive pattern repetitively disposed in at least one shape among a diamond shape, a rhombus shape, a trapezoidal wave shape, a triangular wave shape, a sawtooth wave shape, a sine wave shape, a circular shape, and an omega ((2) shape, but the embodiments of the present specification are not limited thereto. Accordingly, to minimize or reduce the stress concentrated on the plurality of link lines LL and the resulting cracks, the plurality of link lines LL may be formed in various shapes including the above-described shapes, but the embodiments of the present specification are not limited thereto.

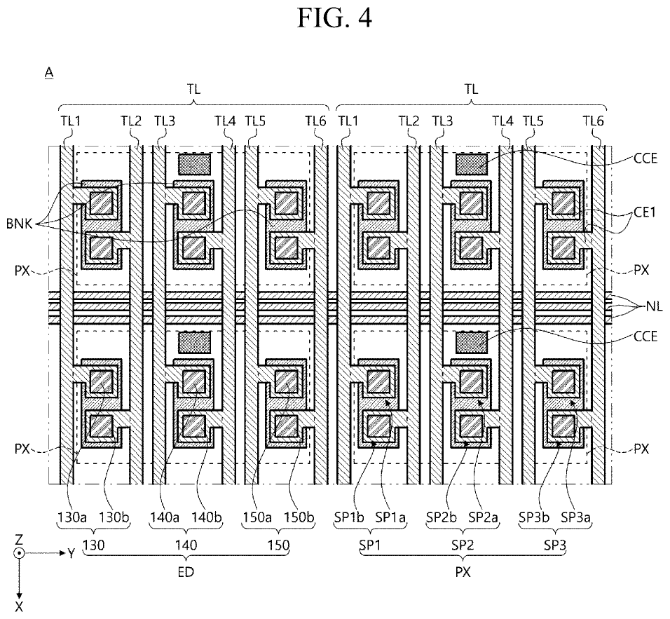

FIGS. 4 to 6 are plan views illustrating the display device according to the embodiment of the present specification.

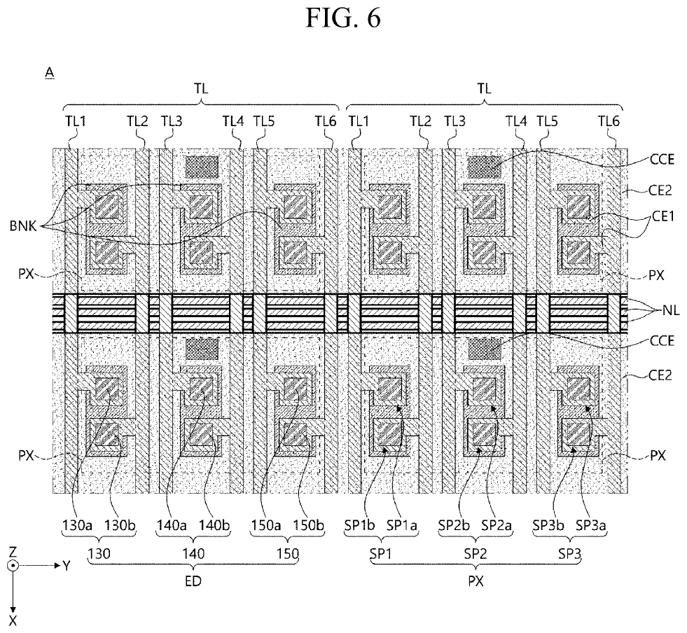

FIGS. 4 and 6 are enlarged views of a display area that includes a plurality of pixels. FIGS. 4 and 6 are partially enlarged views illustrating portion A of FIG. 3.

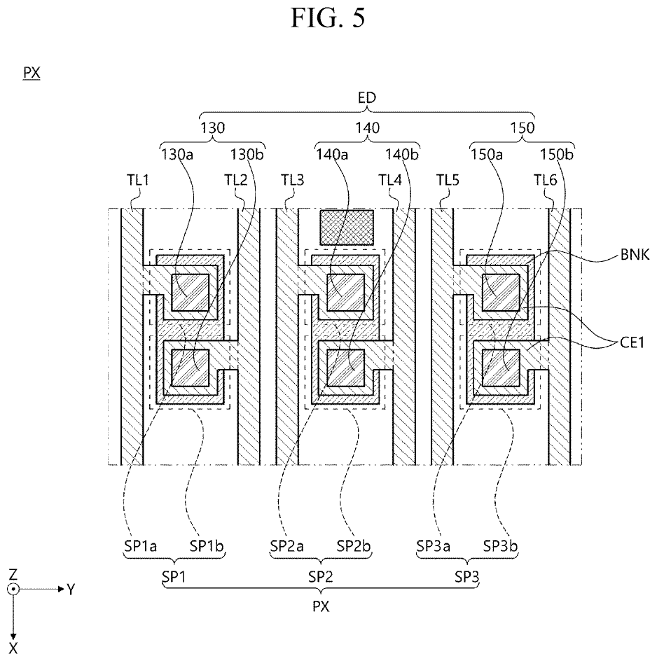

FIG. 5 is an enlarged view of a display area that includes one pixel. FIG. 5 is a partially enlarged view illustrating one pixel PX.

FIGS. 4 and 5 illustrate only a plurality of signal lines TL, a plurality of communication lines NL, a plurality of first electrodes CE1, a plurality of banks BNK, and a plurality of light-emitting elements ED, but the embodiments of the present specification are not limited thereto. FIG. 6 is an enlarged plan view of FIG. 4, in which a plurality of second electrodes CE2 are additionally disposed.

As shown in FIGS. 4 and 5, a plurality of pixels PX, each composed of a plurality of sub-pixels, may be disposed in the display area AA. Each of the plurality of sub-pixels includes a light-emitting element ED and may emit light independently. The plurality of sub-pixels may be disposed in a matrix form, forming a plurality of rows and a plurality of columns, but the embodiments of the present specification are not limited thereto.

The plurality of sub-pixels may include a first sub-pixel SP1, a second sub-pixel SP2, and a third sub-pixel SP3. For example, one of the first sub-pixel SP1, the second sub-pixel SP2, and the third sub-pixel SP3 may be a red sub-pixel, another one thereof may be a green sub-pixel, and the remaining one thereof may be a blue sub-pixel. The types of the plurality of sub-pixels are examples, and the embodiments of the present specification are not limited thereto.

Each of the plurality of pixels PX may include one or more first sub-pixels SP1, one or more second sub-pixels SP2, and one or more third sub-pixels SP3. For example, one pixel PX may include a pair of first sub-pixels SP1, a pair of second sub-pixels SP2, and a pair of third sub-pixels SP3. The pair of first sub-pixels SP1 may be composed of a 1-1 sub-pixel SPla and a 1-2 sub-pixel SP1b. The pair of second sub-pixels SP2 may be composed of a 2-1 sub-pixel SP2a and a 2-2 sub-pixel SP2b. The pair of third sub-pixels SP3 may be composed of a 3-1 sub-pixel SP3a and a 3-2 sub-pixel SP3b. For example, one pixel PX may include the 1-1 sub-pixel SPla, the 1-2 sub-pixel SP1b, the 2-1 sub-pixel SP2a, the 2-2 sub-pixel SP2b, the 3-1 sub-pixel SP3a, and the 3-2 sub-pixel SP3b, but the embodiments of the present specification are not limited thereto.

The plurality of sub-pixels constituting one pixel PX may be arranged in various ways. For example, in one pixel PX, the pair of first sub-pixels SP1 may be disposed in the same column, the pair of second sub-pixels SP2 may be disposed in the same column, and the pair of third sub-pixels SP3 may be disposed in the same column. The first sub-pixel SP1, the second sub-pixel SP2, and the third sub-pixel SP3 may be disposed in the same row. The number and arrangement of the plurality of sub-pixels constituting one pixel PX are examples, and the embodiments of the present specification are not limited thereto.

A plurality of signal lines TL may be disposed in areas between the plurality of sub-pixels. The plurality of signal lines TL may extend in a column direction between the plurality of sub-pixels. The plurality of signal lines TL may be lines that transmit an anode voltage output from the pixel driving circuit PD to the plurality of sub-pixels. For example, the plurality of signal lines TL may be electrically connected to the plurality of pixel driving circuits PD and the first electrodes CE1 of the plurality of sub-pixels. The anode voltage output from the pixel driving circuit PD may be transmitted to the first electrodes CE1 of the plurality of sub-pixels through the plurality of signal lines TL. For example, the first electrode CE1 may be an electrode that is electrically connected to an anode 134 of the light-emitting element ED. Thus, the anode voltage transmitted through the signal line TL may be transmitted to the anode 134 of the light-emitting element ED through the first electrode CE1.

Accordingly, the structure of the display device 1000 may be simplified by using the pixel driving circuit PD, in which a plurality of pixel circuits are integrated, instead of forming a plurality of transistors and a storage capacitor in each of the plurality of sub-pixels. In addition, as the circuits disposed in each of the plurality of sub-pixels are integrated into one pixel driving circuit PD, high-efficiency and low-power operation may be enabled. The integration of the circuits disposed in each of the plurality of sub-pixels into one pixel driving circuit PD means that the pixel driving circuit PD includes a plurality of pixel circuits capable of driving a plurality of light-emitting elements ED. The plurality of light-emitting elements ED may be driven by one pixel driving circuit PD in which a plurality of pixel circuits are integrated. For example, a 1-1 light-emitting element 130a, a 2-1 light-emitting element 140a, and a 3-1 light-emitting element 150a may be driven by one pixel driving circuit PD in which a plurality of pixel circuits are integrated.

The plurality of signal lines TL may include a first signal line TL1, a second signal line TL2, a third signal line TL3, a fourth signal line TL4, a fifth signal line TL5, and a sixth signal line TL6. The first signal line TL1 and the second signal line TL2 may be electrically connected to the pair of first sub-pixels SP1, respectively. The third signal line TL3 and the fourth signal line TL4 may be electrically connected to the pair of second sub-pixels SP2, respectively. The fifth signal line TL5 and the sixth signal line TL6 may be electrically connected to the pair of third sub-pixels SP3, respectively.

The first signal line TL1 may be disposed on one side of the pair of first sub-pixels SP1, and the second signal line TL2 may be disposed on the other side of the pair of first sub-pixels SP1. The first signal line TL1 may be electrically connected to the first electrode CE1 of one of the pair of first sub-pixels SP1, for example, the 1-1 sub-pixel SPla. The second signal line TL2 may be electrically connected to the first electrode CE1 of the other of the pair of first sub-pixels SP1, for example, the 1-2 sub-pixel SP1b.

The third signal line TL3 may be disposed on one side of the pair of second sub-pixels SP2, and the fourth signal line TL4 may be disposed on the other side of the pair of second sub-pixels SP2. For example, the third signal line TL3 may be disposed adjacent to the second signal line TL2. The third signal line TL3 may be electrically connected to the first electrode CE1 of one of the pair of second sub-pixels SP2, for example, the 2-1 sub-pixel SP2a. The fourth signal line TL4 may be electrically connected to the first electrode CE1 of the other of the pair of second sub-pixels SP2, for example, the 2-2 sub-pixel SP2b.

The fifth signal line TL5 may be disposed on one side of the pair of third sub-pixels SP3, and the sixth signal line TL6 may be disposed on the other side of the pair of third sub-pixels SP3. For example, the fifth signal line TL5 may be disposed adjacent to the fourth signal line TL4. The sixth signal line TL6 may be disposed adjacent to the first signal line TL1 connected to the neighboring pixel PX. The fifth signal line TL5 may be electrically connected to the first electrode CE1 of one of the pair of third sub-pixels SP3, for example, the 3-1 sub-pixel SP3a. The sixth signal line TL6 may be electrically connected to the first electrode CE1 of the other of the pair of third sub-pixels SP3, for example, the 3-2 sub-pixel SP3b.

The plurality of signal lines TL may be formed of a conductive material. For example, the plurality of signal lines TL may be formed of a conductive material such as titanium (Ti), aluminum (Al), copper (Cu), molybdenum (Mo), nickel (Ni), chromium (Cr), indium tin oxide (ITO), indium zinc oxide (IZO), or indium gallium zinc oxide (IGZO), but the embodiments of the present specification are not limited thereto. For another example, the plurality of signal lines TL may be formed in a multilayer structure of conductive materials. For example, the plurality of signal lines TL may be formed in a multilayer structure of titanium (Ti)/aluminum (Al)/titanium (Ti)/indium tin oxide (ITO), but the embodiments of the present specification are not limited thereto.

The plurality of communication lines NL may be disposed in areas between the plurality of pixels PX. The plurality of communication lines NL may be disposed to extend in a row direction in the areas between the plurality of pixels PX. The plurality of communication lines NL are disposed in areas between the plurality of second electrodes CE2 and may not overlap the plurality of second electrodes CE2. For example, the plurality of communication lines NL may be lines used for short-range communication, such as near-field communication (NFC). The plurality of communication lines NL may function as antennas. For example, the plurality of communication lines NL may be a plurality of connection lines or the like, but the embodiments of the present specification are not limited thereto.

According to the present specification, the bank BNK may be disposed in each of the plurality of sub-pixels. The plurality of banks BNK may be structures on which the plurality of light-emitting elements ED are mounted. The plurality of banks BNK may guide the positions of the plurality of light-emitting elements ED in a transfer process of transferring the plurality of light-emitting elements ED to the display device 1000. In the transfer process of the plurality of light-emitting elements ED, the plurality of light-emitting elements ED may be transferred onto the plurality of banks BNK. The plurality of banks BNKs may be bank patterns or structures or the like, but the embodiments of the present specification are not limited thereto.

The bank BNK of the first sub-pixel SP1, the bank BNK of the second sub-pixel SP2, and the bank BNK of the third sub-pixel SP3 may be disposed to be spaced apart from each other. The bank BNK of the first sub-pixel SP1, the bank BNK of the second sub-pixel SP2, and the bank BNK of the third sub-pixel SP3 may be configured to be separated from each other. Thus, the banks BNK of the first sub-pixel SP1, the second sub-pixel SP2, and the third sub-pixel SP3, onto which different types of light-emitting elements ED are transferred, may be easily identified.

The bank BNK of the 1-1 sub-pixel SPla and the bank BNK of the 1-2 sub-pixel SP1b may be connected to each other, or may be spaced apart from each other or separately formed. For example, considering the design requirements of the transfer process and the like, the bank BNK of the 1-1 sub-pixel SPla and the bank BNK of the 1-2 sub-pixel SP1b, in which the same type of light-emitting elements ED are disposed, may be connected to each other, or may be spaced apart or separated from each other. In addition, the bank BNK of the 2-1 sub-pixel SP2a and the bank BNK of the 2-2 sub-pixel SP2b may be connected to each other, or may be spaced apart from each other or separately formed. The bank BNK of the 3-1 sub-pixel SP3a and the bank BNK of the 3-2 sub-pixel SP3b may be connected to each other, or may be spaced apart from each other or separately formed. Accordingly, the banks BNK of the pair of first sub-pixels SP1, the banks BNK of the pair of second sub-pixels SP2, and the banks BNK of the pair of third sub-pixels SP3 may be variously formed, but the embodiments of the present specification are not limited thereto.

For example, the plurality of banks BNK may be formed of an organic insulating material. The plurality of banks BNK may be formed of a single layer or multiple layers of an organic insulating material. For example, the plurality of banks BNK may be formed of photoresist, polyimide (PI), or acrylic materials, but the embodiments of the present specification are not limited thereto.

The first electrode CE1 may be disposed in each of the plurality of sub-pixels. The first electrode CE1 may be disposed on the bank BNK. The first electrode CE1 may be electrically connected to one of the plurality of signal lines TL. At least a portion of the first electrode CE1 may extend outward from the bank BNK to be electrically connected to the signal line TL closest to the first electrode CE1. For example, a portion of the first electrode CE1 of the 1-1 sub-pixel SPla may extend to one side area of the 1-1 sub-pixel SPla to be electrically connected to the first signal line TL1, and a portion of the first electrode CE1 of the 1-2 sub-pixel SP1b may extend to the other side area of the 1-2 sub-pixel SP1b to be electrically connected to the second signal line TL2. A portion of the first electrode CE1 of the 2-1 sub-pixel SP2a may extend to one side area of the 2-1 sub-pixel SP2a to be electrically connected to the third signal line TL3, and a portion of the first electrode CE1 of the 2-2 sub-pixel SP2b may extend to the other side area of the 2-2 sub-pixel SP2b to be electrically connected to the fourth signal line TL4. A portion of the first electrode CE1 of the 3-1 sub-pixel SP3a may extend to one side area of the 3-1 sub-pixel SP3a to be electrically connected to the fifth signal line TL5, and a portion of the first electrode CE1 of the 3-2 sub-pixel SP3b may extend to the other side area of the 3-2 sub-pixel SP3b to be electrically connected to the sixth signal line TL6.

The first electrode CE1 may be electrically connected to the anode 134 of the light-emitting element ED, and may transmit the anode voltage output from the pixel driving circuit PD to the light-emitting element ED through the signal line TL. Different voltages may be applied to the first electrode CE1 of each of the plurality of sub-pixels depending on the displayed image. For example, different voltages may be applied to the first electrode CE1 of each of the plurality of sub-pixels. Accordingly, the first electrode CE1 may be a pixel electrode, but the embodiments of the present specification are not limited thereto.

The first electrode CE1 may be formed of a conductive material. For example, the first electrodes CE1 may be configured integrally with the plurality of signal lines TL. For example, the first electrodes CE1 may be formed of the same conductive material as the plurality of signal lines TL, but the embodiments of the present specification are not limited thereto. For example, the first electrode CE1 may be formed of a conductive material such as titanium (Ti), aluminum (Al), copper (Cu), molybdenum (Mo), nickel (Ni), chromium (Cr), indium tin oxide (ITO), indium zinc oxide (IZO), or indium gallium zinc oxide (IGZO), but the embodiments of the present specification are not limited thereto. For another example, the first electrode CE1 may be formed of a multilayer structure of conductive materials. For example, the plurality of first electrodes CE1 may be formed in a multilayer structure of titanium (Ti)/aluminum (Al)/titanium (Ti)/indium tin oxide (ITO), but the embodiments of the present specification are not limited thereto.

The light-emitting element ED may be disposed in each of the plurality of sub-pixels. Each of the plurality of light-emitting elements ED may be either a light-emitting diode (LED) or a micro light-emitting diode (micro LED), but the embodiments of the present specification are not limited thereto. The plurality of light-emitting elements ED may be disposed on the banks BNK and the first electrodes CE1. The plurality of light-emitting elements ED may be disposed on the first electrodes CE1, and may be electrically connected to the first electrodes CE1. Thus, the light-emitting element ED may emit light by receiving the anode voltage from the pixel driving circuit PD through the signal line TL and the first electrode CE1.

The plurality of light-emitting elements ED may include a first light-emitting element 130, a second light-emitting element 140, and a third light-emitting element 150. The first light-emitting element 130, the second light-emitting element 140, and the third light-emitting element 150 may all be inorganic light-emitting elements. The first light-emitting element 130 may be disposed in the first sub-pixel SP1. The second light-emitting element 140 may be disposed in the second sub-pixel SP2. The third light-emitting element 150 may be disposed in the third sub-pixel SP3. For example, one of the first light-emitting element 130, the second light-emitting element 140, and the third light-emitting element 150 may be a red light-emitting element, another one thereof may be a green light-emitting element, and the remaining one thereof may be a blue light-emitting element, but the embodiments of the present specification are not limited thereto. Accordingly, by combining red light, green light, and blue light emitted from the plurality of light-emitting elements ED, various colors of light, including white light, may be implemented. The types of the plurality of light-emitting elements ED are examples, and the embodiments of the present specification are not limited thereto.

The first light-emitting element 130 may include a 1-1 light-emitting element 130a disposed in the 1-1 sub-pixel SPla and a 1-2 light-emitting element 130b disposed in the 1-2 sub-pixel SP1b. The second light-emitting element 140 may include a 2-1 light-emitting element 140a disposed in the 2-1 sub-pixel SP2a and a 2-2 light-emitting element 140b disposed in the 2-2 sub-pixel SP2b. The third light-emitting element 150 may include a 3-1 light-emitting element 150a disposed in the 3-1 sub-pixel SP3a and a 3-2 light-emitting element 150b disposed in the 3-2 sub-pixel SP3b.

As shown in FIGS. 4 to 6, the second electrode CE2 may be disposed in each of the plurality of sub-pixels. The second electrode CE2 may be disposed on the light-emitting element ED. The second electrodes CE2 may be electrically connected to the pixel driving circuit PD through a plurality of contact electrodes CCE.

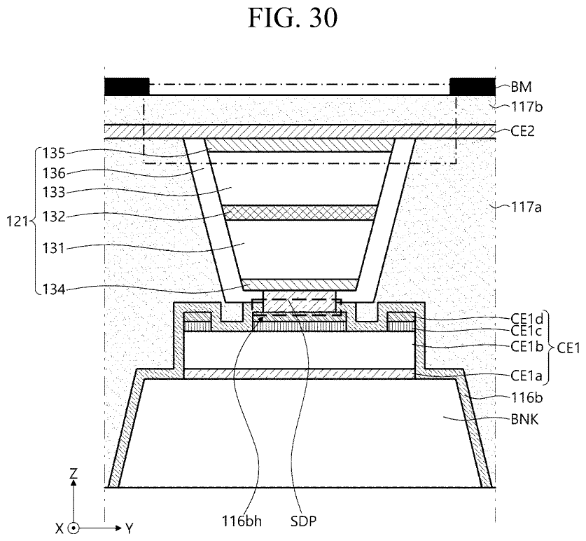

For example, the second electrode CE2 may be electrically connected to a cathode 135 of the light-emitting element ED (see FIG. 30), and may transmit a cathode voltage output from the pixel driving circuit PD to the light-emitting element ED. The same cathode voltage may be applied to the second electrode CE2 of each of the plurality of sub-pixels. For example, the same voltage may be applied to the second electrodes CE2 of each of the plurality of sub-pixels and the cathode 135 of the light-emitting element ED. Accordingly, the second electrode CE2 may be a common electrode, but the embodiments of the present specification are not limited thereto.

At least some of the plurality of sub-pixels may share the second electrode CE2. At least some of the second electrodes CE2 of each of the plurality of sub-pixels may be electrically connected to each other. Since the same voltage is applied to the second electrodes CE2, the second electrodes CE2 of at least some of the sub-pixels may be shared. For example, the second electrodes CE2 of at least some of the plurality of pixels PX disposed in the same row may be connected to each other. For example, one second electrode CE2 may be disposed in the plurality of pixels PX. One second electrode CE2 may be disposed for every n sub-pixels.

For example, some of the second electrodes CE2 of each of the plurality of sub-pixels may be spaced apart from each other or separately disposed. For example, the second electrodes CE2 connected to the pixels PX in an nth row and the second electrodes CE2 connected to the pixels PX in a (n+1)th row may be spaced apart from each other or separately disposed. For example, the plurality of second electrodes CE2 may be disposed to be spaced apart from each other with the plurality of communication lines NL extending in the row direction interposed therebetween. Accordingly, the number of sub-pixels may be greater than the number of second electrodes CE2. For another example, all of the second electrodes CE2 of the plurality of sub-pixels may be interconnected so that only one second electrode CE2 is disposed on the substrate 110, but the embodiments of the present specification are not limited thereto.

The plurality of second electrodes CE2 may be formed of a transparent conductive material, but the embodiments of the present specification are not limited thereto. The plurality of second electrodes CE2 may be formed of a transparent conductive material so that light emitted from the light-emitting elements ED is directed upward through the second electrodes CE2. For example, the second electrode CE2 may be formed of a transparent conductive material such as indium tin oxide (ITO), indium zinc oxide (IZO), or indium gallium zinc oxide (IGZO), but the embodiments of the present specification are not limited thereto.

A plurality of contact electrodes CCE may be disposed on the substrate 110. For example, the plurality of contact electrodes CCE may be disposed to be spaced apart from the plurality of banks BNK and the plurality of signal lines TL. Each of the plurality of second electrodes CE2 may overlap at least one contact electrode CCE. For example, one second electrode CE2 may overlap the plurality of contact electrodes CCE.

For example, the plurality of contact electrodes CCE may be electrically connected to the plurality of second electrodes CE2. The plurality of contact electrodes CCE may be disposed between the substrate 110 and the plurality of second electrodes CE2, and may transmit the cathode voltage output from the pixel driving circuit PD to the second electrodes CE2.

For example, when micro LEDs are used as the light-emitting elements ED, a plurality of micro LEDs may be formed on a wafer and transferred onto the substrate 110 of the display device 1000 to manufacture the display device 1000. During the process of transferring the plurality of light-emitting elements ED having a micro size from the wafer to the substrate 110, various defects may occur. For example, in some sub-pixels, a non-transfer defect may occur in which the light-emitting element ED is not transferred, and in other sub-pixels, a defect may occur in which the light-emitting element ED is transferred out of an intended position due to misalignment. In addition, although the transfer process proceeds normally, the transferred light-emitting element ED itself may be defective. Thus, in consideration of the defects that may occur during the transfer process of the plurality of light-emitting elements ED, the plurality of light-emitting elements ED of the same type may be transferred onto one sub-pixel. A lighting test may be performed on the plurality of light-emitting elements ED, and ultimately, only one light-emitting element ED that is determined to be normal may be used.

For example, the 1-1 light-emitting element 130a and the 1-2 light-emitting element 130b may be transferred together onto one pixel PX, and may be inspected to determine whether there is a defect. When both the 1-1 light-emitting element 130a and the 1-2 light-emitting element 130b are determined to be normal, only the 1-1 light-emitting element 130a may be used, and the 1-2 light-emitting element 130b may not be used. For another example, when only the 1-2 light-emitting element 130b among the 1-1 light-emitting element 130a and the 1-2 light-emitting element 130b is determined to be normal, the 1-1 light-emitting element 130a may not be used, and only the 1-2 light-emitting element 130b may be used. Accordingly, even when the plurality of light-emitting elements ED of the same type are transferred onto one pixel PX, ultimately, only one light-emitting element ED may be used.

Accordingly, one of the pair of light-emitting elements ED may be a main (or primary) light-emitting element ED, and the other one thereof may be a redundancy light-emitting element ED. The redundancy light-emitting element ED may be a spare light-emitting element ED transferred in preparation for a defective main light-emitting element ED. In the event of a defective main light-emitting element ED, the redundancy light-emitting element ED may be used as a replacement. Accordingly, by transferring both the main light-emitting element ED and the redundancy light-emitting element ED onto one pixel PX, the degradation of display quality due to the failure of the main light-emitting element ED or the redundancy light-emitting element ED may be minimized or reduced.

For example, the 1-1 light-emitting element 130a, the 2-1 light-emitting element 140a, and the 3-1 light-emitting element 150a transferred onto one pixel PX may be used as main light-emitting elements ED, and the 1-2 light-emitting element 130b, the 2-2 light-emitting element 140b, and the 3-2 light-emitting element 150b transferred onto one pixel PX may be used as redundancy light-emitting elements ED.

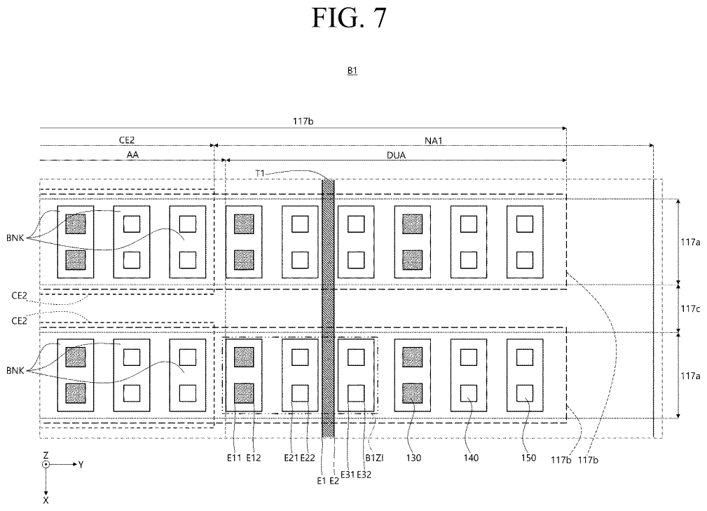

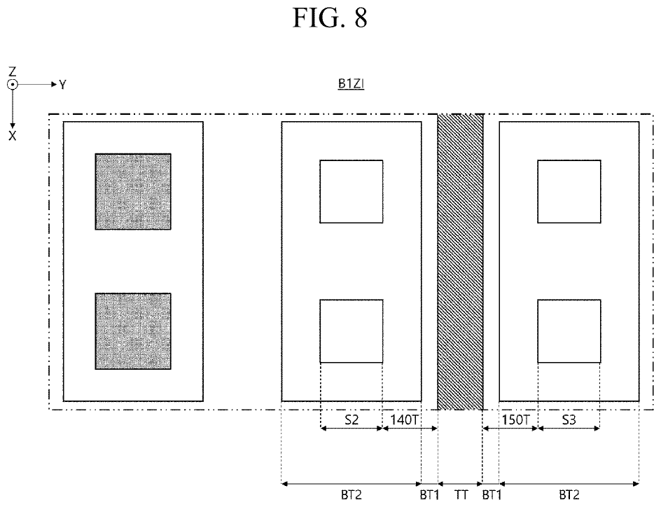

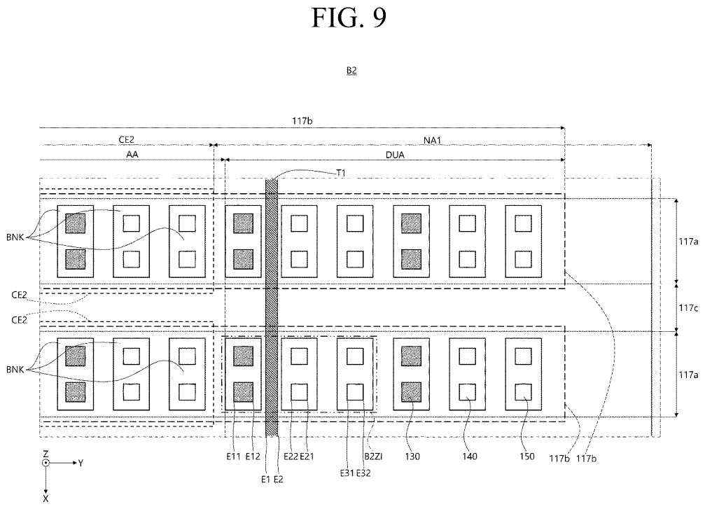

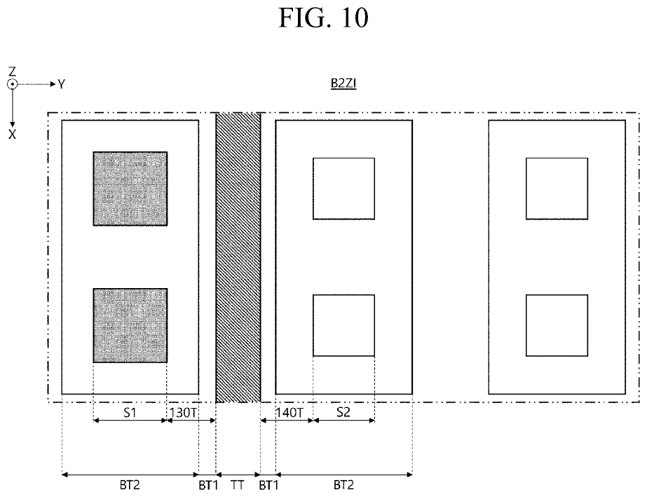

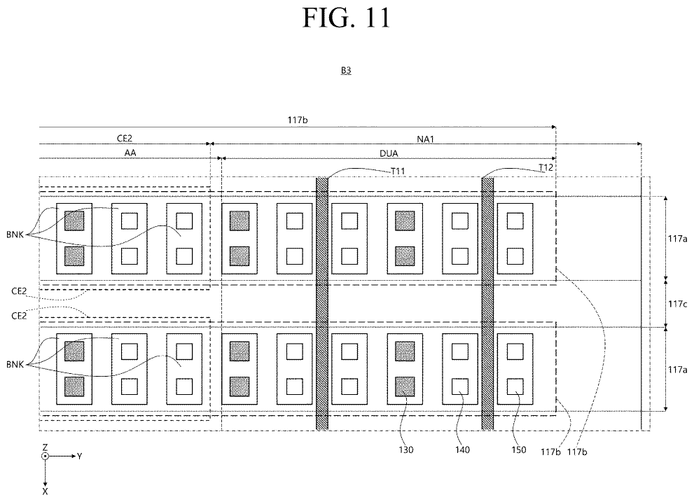

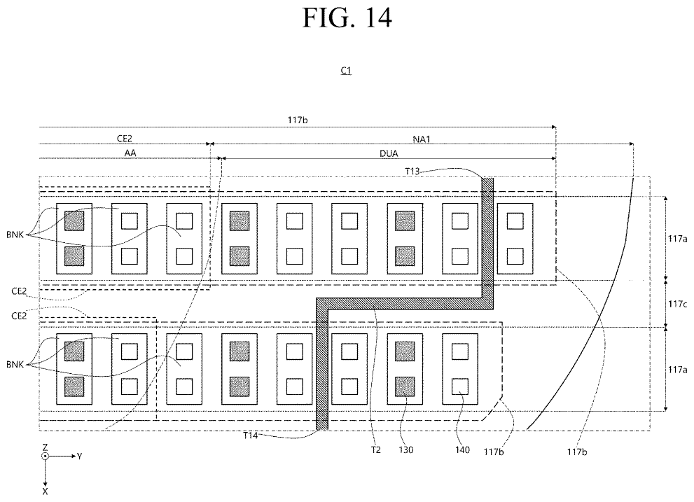

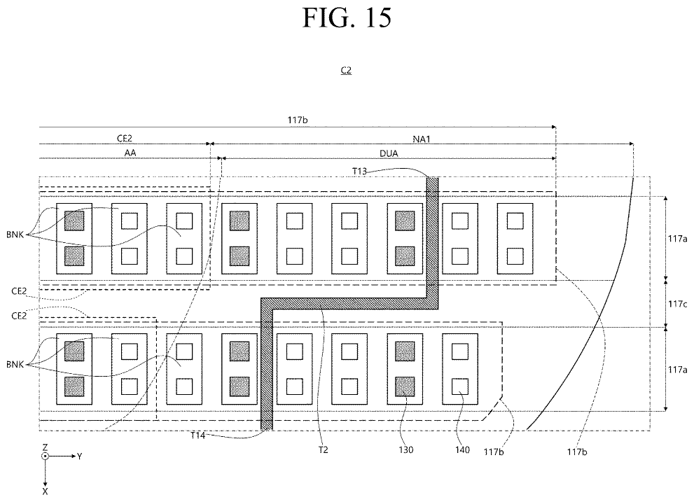

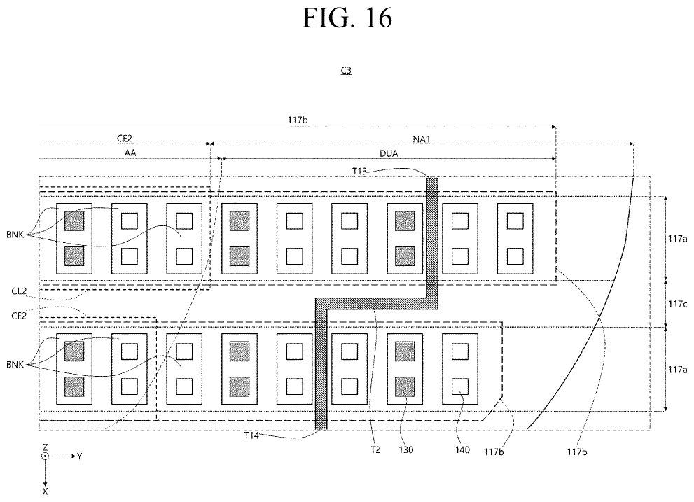

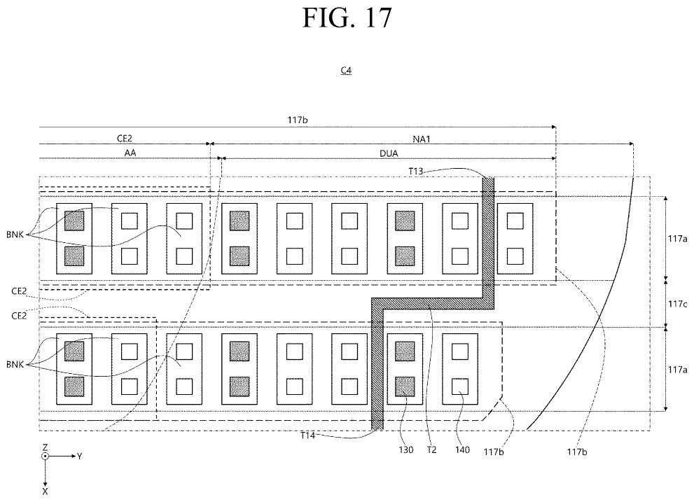

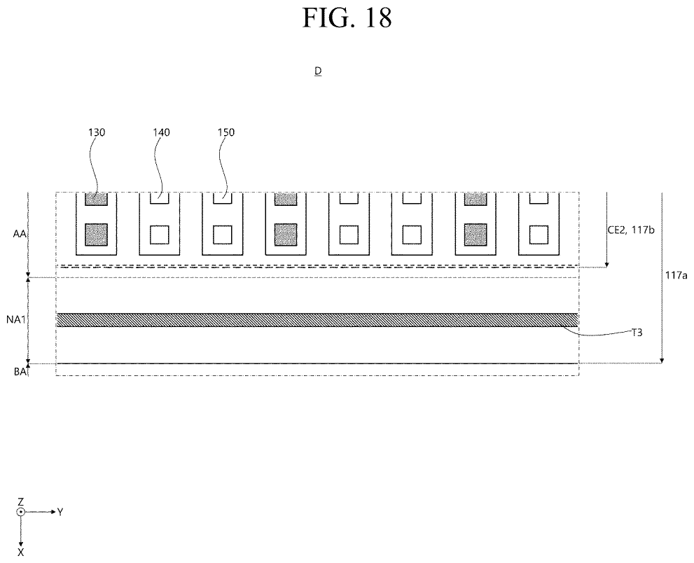

FIGS. 7 and 8 are plan views illustrating a display device according to an embodiment of the present specification. FIGS. 9 and 10 are plan views illustrating a display device according to a comparative example with respect to FIG. 7. FIGS. 11 to 13 are plan views illustrating display devices according to modified examples of the embodiment of the present specification. FIG. 14 is a plan view illustrating a display device according to an embodiment of the present specification. FIG. 15 is a plan view illustrating a display device according to a comparative example with respect to FIG. 14. FIGS. 16 and 17 are plan views illustrating display devices according to modified examples of the embodiment of the present specification. FIG. 18 is a plan view illustrating a display device according to an embodiment of the present specification.

FIGS. 7, 9, and 11 to 13 are partially enlarged views B1, B2, B3, B4, and B5, each illustrating portion B of FIG. 3. FIG. 7 illustrates a display device according to a first embodiment. FIG. 9 illustrates a display device according to a first comparative example. FIGS. 11 to 13 illustrate a display device according to first to third modified examples of the first embodiment.

FIG. 8 is a partially enlarged view of portion B1ZI of FIG. 7. FIG. 10 is a partially enlarged view of portion B2ZI of FIG. 9. The same reference numerals are assigned to configurations that perform substantially the same function in the embodiments or plan views, and detailed descriptions thereof are omitted.

As shown in FIG. 7, the display device according to the first embodiment may include a display area AA and a first non-display area NA1. The display area AA may include a plurality of light-emitting elements 130, 140, and 150, second electrodes CE2, a first optical layer 117a, a second optical layer 117b, and a third optical layer 117c. The first non-display area NA1 may include a plurality of light-emitting elements 130, 140, and 150, a first optical layer 117a, a second optical layer 117b, and a third optical layer 117c.

The plurality of light-emitting elements 130, 140, and 150 disposed in the display area AA may emit light due to a high-potential power voltage applied to first electrodes as a plurality of second electrodes CE2 are disposed. The second electrode CE2 may be formed to entirely cover the plurality of pixels so as to be common to the plurality of pixels. The second electrode CE2 may be formed to be common only to the plurality of light-emitting elements 130, 140, and 150 disposed in each pixel.

The plurality of light-emitting elements 130, 140, and 150 disposed in the display area AA and the first non-display area NA1 may include a first light-emitting element 130, a second light-emitting element 140, and a third light-emitting element 150. The first light-emitting element 130, the second light-emitting element 140, and the third light-emitting element 150 may implement a first color, a second color, and a third color, respectively. The first to third colors may each be any one selected from red, green, and blue without overlapping each other, but the embodiments of the present specification are not limited thereto. For example, the first color may be red, the second color may be green, and the third color may be blue, but the present specification is not limited thereto.

The first non-display area NA1 may include a dummy area DUA. The dummy area DUA may include dummy pixels including a plurality of dummy light-emitting elements. The second electrode CE2 may not be disposed in the first non-display area NA1 in which the plurality of dummy light-emitting elements are disposed. Accordingly, even when a high-potential power voltage is applied to the first electrode disposed in the dummy light-emitting element, the dummy light-emitting element may not emit light.

A first trench T1 may be disposed between the plurality of light-emitting elements 130, 140, and 150. The first trench T1 may be disposed to extend in a first direction (for example, an X-axis direction). The first trench T1 may be disposed between the second light-emitting element 140 and the third light-emitting element 150, but the present specification is not limited thereto. As the trench is disposed between the second light-emitting element 140 and the third light-emitting element 150, which are relatively small in size, a design margin of the display panel can be secured. Accordingly, the probability of defective transfer of the light-emitting elements in the manufacturing process of the display panel may be reduced. Thus, the productivity of the display device can be improved. Further, the display panel can be protected as the first trench T1 is disposed. For example, effects such as moisture-proofing may be implemented. Thus, the reliability of the display device may be improved.

One pixel may include a first light-emitting element 130, a second light-emitting element 140, and a third light-emitting element 150. The third optical layer 117c may be disposed between a plurality of pixels disposed in the first direction (for example, the X-axis direction). For example, the third optical layer 117c may be disposed to extend in a second direction (for example, a Y-axis direction) that intersects the first direction.

The first optical layer 117a and the second optical layer 117b may be disposed to overlap each other in a planar direction of the display panel (e.g., a Z-axis direction) in an area in which the pixels or dummy pixels are disposed. The third optical layer 117c may be disposed between a plurality of first optical layers 117a or a plurality of second optical layers 117b.

In one embodiment, the first optical layer 117a may extend to one end of the display panel. The second optical layer 117b may extend to the dummy area DUA in which the dummy pixels are disposed. The second optical layer 117b may be disposed on the first optical layer 117a. Thus, a thickness of the optical layer of the display panel may decrease in the second direction (for example, the Y-axis direction).

A first passivation layer may be disposed across the entirety of the display area AA and the first non-display area NA1. The display device according to an example embodiment of the present specification may prevent or suppress moisture penetration from the outside of the display device by including the first passivation layer and the first trench T1, thereby improving the lifespan of the display device. Accordingly, long-term power consumption may be reduced, and low-power operation may be achieved.

As shown in FIG. 9, the display device according to the first comparative example may include a display area AA and a first non-display area NA1.

A first trench T1 may be disposed between a plurality of light-emitting elements 130, 140, and 150. The first trench T1 may be disposed to extend in the first direction (for example, the X-axis direction). The first trench T1 may be disposed between a first light-emitting element 130 and a second light-emitting element 140.

As shown in FIGS. 7 to 10, the embodiment according to the present specification may include the first light-emitting element 130 having a first size and implementing a first color, the second light-emitting element 140 having a second size different from the first size and implementing a second color, and the third light-emitting element 150 having a third size different from the first size and implementing a third color.

In one embodiment, the second size and the third size may be substantially the same. The first size may be greater than each of the second size and the third size.

As shown in FIGS. 7 and 8, the first trench T1 may be disposed between the second light-emitting element 140 and the third light-emitting element 150. The first trench T1 may include a first end E1 and a second end E2 facing each other. The second light-emitting element 140 may include a 2-1 end E21 relatively far from the first end E1 and a 2-2 end E22 relatively close to the first end E1. The 2-1 end E21 and the 2-2 end E22 may be disposed to face each other. The third light-emitting element 150 may include a 3-1 end E31 relatively close to the second end E2 and a 3-2 end E32 relatively far from the second end E2. The 3-1 end E31 and the 3-2 end E32 may be disposed to face each other.

A distance BT1 from the first end E1 to one end of the bank on which the second light-emitting element 140 is disposed and a distance BT1 from the second end E2 to one end of the bank on which the third light-emitting element 150 is disposed may be substantially the same. A distance BT2 from one end to the other end of the bank on which the second light-emitting element 140 is disposed and a distance BT2 from one end to the other end of the bank on which the third light-emitting element 150 is disposed may be substantially the same. A distance TT between the first end E1 and the second end E2 may be greater than the distance BT1 from the first end E1 to one end of the bank on which the corresponding light-emitting element is disposed. The distance TT between the first end E1 and the second end E2 may be less than the distance BT2 from one end to the other end of the bank on which the corresponding light-emitting element is disposed.

Referring again to FIGS. 7 to 10, the second light-emitting element 140 may have the second size. The second size may be proportional to a distance S2 between the 2-1 end E21 and the 2-2 end E22. The third light-emitting element 150 may have the third size. The third size may be proportional to a distance S3 between the 3-1 end E31 and the 3-2 end E32. The third size may be substantially the same as the second size. By disposing the first trench T1 between the second light-emitting element 140 and the third light-emitting element 150, a distance 140T between the first end E1 and the 2-2 end E22 may be greater than a distance 130T between the first end E1 and a 1-2 end E12 in the first comparative example according to FIG. 10. Accordingly, the design margin of the light-emitting element may be secured, which may reduce the probability of defective transfer of the light-emitting elements in the manufacturing process of the display panel. Accordingly, the productivity of the display device may be improved.

A distance between the center of the 1-1 end E11 and the 1-2 end E12 and the center of the 2-1 end E21 and the 2-2 end E22 may be defined. A distance between the center of the 2-1 end E21 and the 2-2 end E22 and the center of the 3-1 end E31 and the 3-2 end E32 may be defined. In one embodiment, the two distances may be set to be substantially the same.

In FIG. 7, a distance between the 1-2 end E12 and the 2-1 end E21 may be less than a distance between the 2-2 end E22 and the 3-1 end E31. Also in FIG. 9, the distance between the 1-2 end E12 and the 2-1 end E21 may be less than the distance between the 2-2 end E22 and the 3-1 end E31.

In FIG. 7, a distance between the 1-1 end E11 and the 2-2 end E22 may be greater than a distance between the 2-1 end E21 and the 3-2 end E32. Also in FIG. 9, the distance between the 1-1 end E11 and the 2-2 end E22 may be greater than the distance between the 2-1 end E21 and the 3-2 end E32.

Referring again to FIGS. 7 and 8, the distance TT between the first end E1 and the second end E2 may be less than each of the distance S2 between the 2-1 end E21 and the 2-2 end E22 and the distance S3 between the 3-1 end E31 and the 3-2 end E32. The distance TT between the first end E1 and the second end E2 may be less than each of the distance 140T between the first end E1 and the 2-2 end E22 and a distance 150T between the second end E2 and the 3-1 end E31. The distance 140T between the first end E1 and the 2-2 end E22 and the distance 150T between the second end E2 and the 3-1 end E31 may each be greater than each of the distance S2 between the 2-1 end E21 and the 2-2 end E22 and the distance S3 between the 3-1 end E31 and the 3-2 end E32. The distance 140T between the first end E1 and the 2-2 end E22 may be substantially the same as the distance 150T between the second end E2 and the 3-1 end E31.

As shown in FIGS. 9 and 10, the first trench T1 may include the first end E1 and the second end E2 facing each other. The first light-emitting element 130 may include the 1-1 end E11 relatively far from the first end E1 and the 1-2 end E12 relatively close to the first end E1. The 1-1 end E11 and the 1-2 end E12 may be disposed to face each other. The second light-emitting element 140 may include the 2-1 end E21 relatively far from the second end E2 and the 2-2 end E22 relatively close to the second end E2.

The first light-emitting element 130 may have a first size. The first size may be proportional to the distance S1 between the 1-1 end E11 and the 1-2 end E12. The second light-emitting element 140 may have a second size. The second size may be proportional to the distance S2 between the 2-1 end E21 and the 2-2 end E22. The second size may be different from the first size. The second size may be smaller than the first size. By forming the first size to be relatively large, the light efficiency of the first light-emitting element 130 may be improved. As the first size is formed to be relatively large, the distance 130T between the first end E1 and the 1-2 end E12 may be less than the distance 140T between the second end E2 and the 2-2 end E22. Accordingly, the display device according to the embodiment of the present specification may secure a design margin by disposing the first trench T1 between the second light-emitting element 140 and the third light-emitting element 150, which are relatively small in size.

For example, a loss of (missing) light-emitting elements may be prevented or reduced in a process of forming trenches after a transfer process is completed. When a trench is formed in a display panel in which transferred light-emitting elements are disposed, there is a possibility that the light-emitting elements may be lost, and when the light-emitting elements are lost, there may be an issue in which a moisture penetration path into the display device may be created. Accordingly, by securing a design margin, the loss of light-emitting elements may be prevented or reduced, and ultimately, the operational reliability and lifespan of the display device may be improved.

As shown in FIG. 11, the display device according to the first modified example may include a display area AA and a first non-display area NA1.

A 1-1 trench T11 and/or a 1-2 trench T12 may be disposed between a plurality of light-emitting elements 130, 140, and 150. The 1-1 trench T11 and/or the 1-2 trench T12 may be disposed to extend in the first direction (for example, the X-axis direction). The 1-1 trench T11 may be disposed between a second light-emitting element 140 and a third light-emitting element 150, and the 1-2 trench T12 may be disposed between another second light-emitting element 140 and another third light-emitting element 150, but the present specification is not limited thereto. As the trench is disposed between the second light-emitting element 140 and the third light-emitting element 150, which are relatively small in size, a design margin of the display panel can be secured. Further, by including a plurality of trenches, effects such as moisture-proofing may be improved.

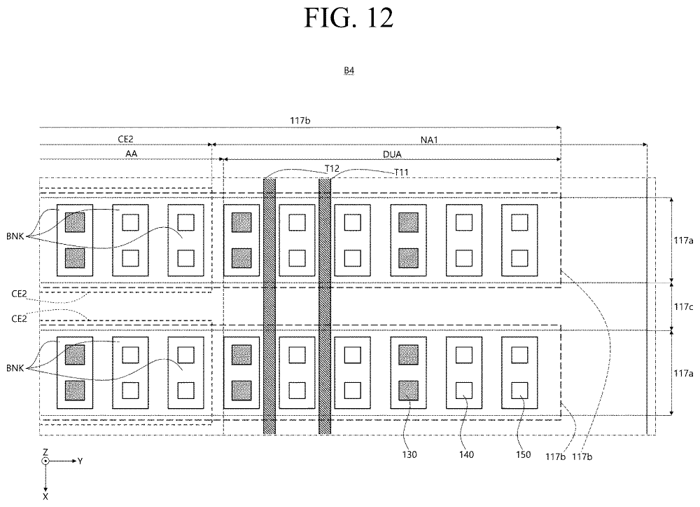

As shown in FIG. 12, the display device according to the second modified example may include a display area AA and a first non-display area NA1.

A 1-1 trench T11 and/or a 1-2 trench T12 may be disposed between a plurality of light-emitting elements 130, 140, and 150. The 1-1 trench T11 and/or the 1-2 trench T12 may be disposed to extend in the first direction (for example, the X-axis direction). The 1-1 trench T11 may be disposed between a second light-emitting element 140 and a third light-emitting element 150, and the 1-2 trench T12 may be disposed between the first light-emitting element 130 and the second light-emitting element 140, but the present specification is not limited thereto. As the trench is disposed between the second light-emitting element 140 and the third light-emitting element 150, which are relatively small in size, a design margin of the display panel can be secured. Further, by including a plurality of trenches, effects such as moisture-proofing may be improved.

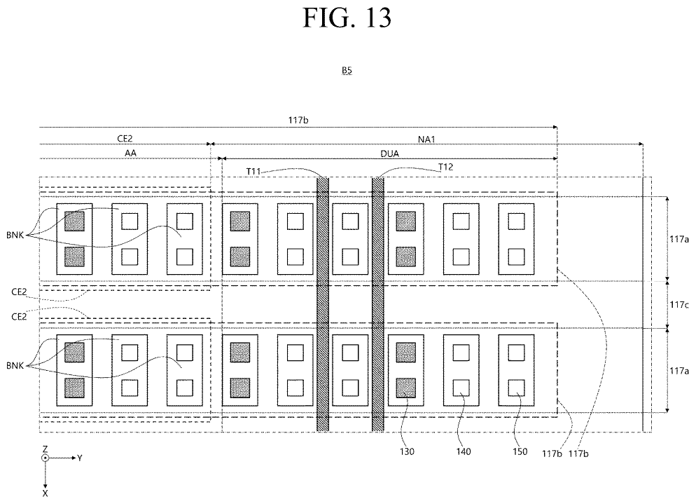

As shown in FIG. 13, the display device according to the third modified example may include a display area AA and a first non-display area NA1.

A 1-1 trench T11 and/or a 1-2 trench T12 may be disposed between a plurality of light-emitting elements 130, 140, and 150. The 1-1 trench T11 and/or the 1-2 trench T12 may be disposed to extend in the first direction (for example, the X-axis direction). The 1-1 trench T11 may be disposed between a second light-emitting element 140 and a third light-emitting element 150, and the 1-2 trench T12 may be disposed between the third light-emitting element 150 and another first light-emitting element 130, but the present specification is not limited thereto. As the trench is disposed between the second light-emitting element 140 and the third light-emitting element 150, which are relatively small in size, a design margin of the display panel can be secured. Further, by including a plurality of trenches, effects such as moisture-proofing may be improved.

FIGS. 14 to 17 are partially enlarged views C1, C2, C3, and C4, each illustrating portion C of FIG. 3. FIG. 14 illustrates a display device according to a second embodiment. FIG. 15 illustrates a display device according to a second comparative example. FIGS. 16 and 17 illustrate display devices according to first and second modified examples of the second embodiment, respectively. The same reference numerals are assigned to configurations that perform substantially the same function in the above-described embodiments, or examples or plan views, and detailed descriptions thereof are omitted.

As shown in FIG. 14, the display device may include rounded corners, but the embodiments of the present specification are not limited thereto. The rounded corner may include a 1-3 trench T13, a 1-4 trench T14, and a second trench T2. The 1-3 trench T13 and the 1-4 trench T14 may be disposed to extend in the first direction. The second trench T2 may be disposed to extend in the second direction intersecting the first direction. As illustrated in the drawings, the first direction and the second direction intersect perpendicularly in the X-axis direction and the Y-axis direction, respectively, but, the directions in which the 1-3 trench T13, the 1-4 trench T14, and the second trench T2 are disposed to extend are not limited thereto. The implementer may adjust the arrangement angles of the trenches through design modifications.

The display device according to the second embodiment may include a display area AA and a first non-display area NA1.

A plurality of light-emitting elements 130, 140, and 150 disposed in the display area AA may emit light due to a high-potential power voltage applied to the first electrodes as the plurality of second electrodes CE2 are disposed. The second electrodes CE2 may be formed to correspond to the shape of the display area AA in accordance with the rounded corner. For example, an area covering the plurality of light-emitting elements 130, 140, and 150 may decrease in the first direction (e.g., the X-axis direction).

The first non-display area NA1 may include a dummy area DUA. The dummy area DUA may also be formed to correspond to the shape of the first non-display area NA1 in accordance with the rounded corner. For example, an area covering the plurality of dummy light-emitting elements may decrease in the first direction (e.g., the X-axis direction).

The 1-3 trench T13, the 1-4 trench T14, and the second trench T2 may be disposed between the plurality of light-emitting elements 130, 140, and 150. The 1-3 trench T13 may be disposed between the second light-emitting element 140 and the third light-emitting element 150. The 1-4 trench T14 may be disposed in the dummy pixel disposed in the first direction (e.g., the X-axis direction) from the dummy pixel including the second light-emitting element 140 and the third light-emitting element 150, in which the 1-3 trench T13 is disposed. The 1-4 trench T14 may be disposed between another second light-emitting element 140 and another third light-emitting element 150. The 1-3 trench T13 may be disposed to be offset from the 1-4 trench T14 in the first direction (e.g., the X-axis direction). The second trench T2 may be disposed between the plurality of pixels. The second trench T2 may be disposed to extend in the second direction (e.g., the Y-axis direction) intersecting the first direction (e.g., the X-axis direction) between the dummy pixels disposed in the first direction. The second trench T2 may be disposed between the plurality of light-emitting elements 130, 140, and 150. The second trench T2 may be disposed between the third light-emitting elements 150, between the first light-emitting elements 130, or between the second light-emitting elements 140, each implementing the same color. Accordingly, the corner of the display panel may be protected. For example, effects such as moisture-proofing may be implemented. Thus, the reliability of the display device may be improved. The embodiment of the present specification includes the rounded corner, but the present specification is not limited thereto. When the corner has a different shape, the trenches disposed to correspond to the corner may be formed by a simple design modification of the above-described embodiment.

A first optical layer 117a, a second optical layer 117b, and a third optical layer 117c may be formed to correspond to the shape of the first non-display area NA1 in accordance with the rounded corner. For example, in the first direction, the area in which the first optical layer 117a, the second optical layer 117b, and the third optical layer 117c overlap the display panel may decrease in size in the first direction.

A first passivation layer may be disposed across the entirety of the display area AA and the first non-display area NA1. The display device according to the embodiment of the present specification may include the first passivation layer, the 1-3 trench T13, the 1-4 trench T14, and the second trench T2, thereby preventing or suppressing moisture penetration from the outside of the display device and improving the lifespan of the display device. Accordingly, long-term power consumption may be reduced, and low-power operation may be achieved.

As shown in FIG. 15, the display device according to the second comparative example may include a display area AA and a first non-display area NA1. A 1-3 trench T13, a 1-4 trench T14, and a second trench T2 may be disposed between a plurality of light-emitting elements 130, 140, and 150. The 1-3 trench T13 may be disposed between a first light-emitting element 130 and a second light-emitting element 140. The 1-4 trench T14 may be disposed between another first light-emitting element 130 and another second light-emitting element 140. As the 1-3 trench T13 and the 1-4 trench T14 are disposed between the relatively large first light-emitting elements 130 and the second light-emitting element 140, the display device according to the second comparative example may have a reduced design margin, which may decrease the yield and productivity of the display device.

As shown in FIG. 16, the display device according to the first modified example may include a display area AA and a first non-display area NA1. A 1-3 trench T13, a 1-4 trench T14, and a second trench T2 may be disposed between a plurality of light-emitting elements 130, 140, and 150. The 1-3 trench T13 may be disposed between a first light-emitting element 130 and a second light-emitting element 140. The 1-4 trench T14 may be disposed between another second light-emitting element 140 and a third light-emitting element 150. The second trench T2 may be disposed between the plurality of pixels. The second trench T2 may be disposed between the third light-emitting elements 150, and/or between the first light-emitting elements 130, each implementing the same color.

As shown in FIG. 17, the display device according to the second modified example may include a display area AA and a first non-display area NA1. A 1-3 trench T13, a 1-4 trench T14, and a second trench T2 may be disposed between a plurality of light-emitting elements 130, 140, and 150. The 1-3 trench T13 may be disposed between a second light-emitting element 140 and a third light-emitting element 150. The 1-4 trench T14 may be disposed between another third light-emitting element 150 and a first light-emitting element 130. The second trench T2 may be disposed between the plurality of pixels. The second trench T2 may be disposed between the first light-emitting elements 130, and/or between the second light-emitting elements 140, each implementing the same color.

FIG. 18 is a partially enlarged view illustrating portion D of FIG. 3. FIG. 18 illustrates a display device according to a third embodiment.

As shown in FIG. 18, the display device according to the third embodiment may include a display area AA and a first non-display area NA1. An end of a second electrode CE2 and end of a second optical layer 117b in the first direction may be formed to meet at substantially the same point. The display area AA may include the second electrode CE2 and the second optical layer 117b.

The display device may include the first non-display area NA1 disposed between a bending area BA and the display area AA. The first non-display area NA1 may include a third trench T3. In addition, the display panel 100 may further include a first trench disposed between the second light-emitting elements and the third light-emitting elements and a second trench disposed between the plurality of light-emitting elements. The third trench T3 may be disposed to extend in the second direction intersecting the first direction. The third trench T3 may be disposed between the bending area BA and the display panel 100 or the display area AA. When the bending area BA is bent, an end of the first non-display area NA1 in the first direction may form one side of the display device. The third trench T3 may block moisture particles penetrating in a direction in which the bending area BA is disposed. Accordingly, the operational reliability of the display device may be improved, thereby extending its lifespan.

A first passivation layer may be disposed across the entirety of the display area AA and the first non-display area NA1. The display device according to the embodiment of the present specification may prevent or suppress moisture penetration from the outside of the display device by including the first passivation layer and the third trench T3, thereby improving the lifespan of the display device. Accordingly, in the long term, power consumption may be reduced, and low-power operation may be achieved.

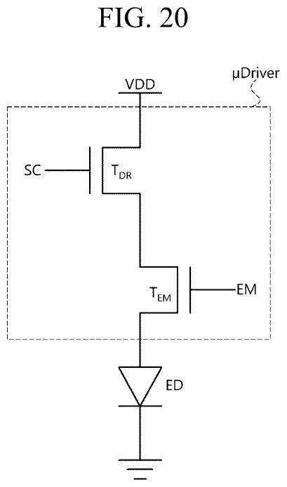

FIG. 20 is a diagram illustrating a circuit structure according to an embodiment of the present specification.

In FIG. 20, an example is illustrated in which one light-emitting element ED is connected to a micro driver μDriver, but the present specification is not limited thereto. For example, eight light-emitting elements ED may be connected to one micro driver μDriver. For another example, 16 light-emitting elements ED may be connected to one micro driver μDriver, or 32 light-emitting elements ED or 64 light-emitting elements ED may be simultaneously connected to one micro driver μDriver. The light-emitting element ED may be a micro light-emitting element (μLED).

The micro driver μDriver may include a driving transistor T_{DR} and a light-emitting transistor T_{EM}, but the embodiments of the present specification are not limited thereto.

For example, the driving transistor T_{DR} has a first electrode to which a high-potential power voltage VDD may be applied, a second electrode to which a first electrode of the light-emitting transistor T_{EM} may be connected, and a gate electrode to which a scan signal SC may be applied. The scan signal SC applied to the gate electrode of the driving transistor T_{DR} may be direct current (DC) power, and a fixed reference voltage (Vref) may be applied for each frame, but the embodiments of the present specification are not limited thereto.

The light-emitting transistor T_{EM} has the first electrode to which the second electrode of the driving transistor T_{DR} may be connected, a second electrode to which the light-emitting element ED may be connected, and a gate electrode to which a light-emission signal EM may be applied. The light-emission signal EM applied to the gate electrode of the light-emitting transistor T_{EM} may be a pulse width modulation (PWM) signal that varies for each frame, but the embodiments of the present specification are not limited thereto.

A first electrode of the light-emitting element ED may be connected to the second electrode of the light-emitting transistor T_{EM}, and a second electrode of the light-emitting element ED may be connected to the ground. For example, the first electrode of the light-emitting element ED may be an anode, and the second electrode of the light-emitting element ED may be a cathode, but the embodiments of the present specification are not limited thereto.

The driving transistor T_{DR} and the light-emitting transistor T_{EM} may each be an n-type transistor or a p-type transistor.

In the micro driver μDriver, the driving transistor T_{DR} may be turned on by the scan signal SC applied from a timing controller (T-CON), and the light-emitting transistor T_{EM} may be turned on by the light-emission signal EM. As a result, a driving current may be applied to the light-emitting element ED via the driving transistor T_{DR} and the light-emitting transistor T_{EM} by the high-potential power voltage VDD applied to the first electrode of the driving transistor T_{DR}, thereby enabling the light-emitting element ED to emit light.

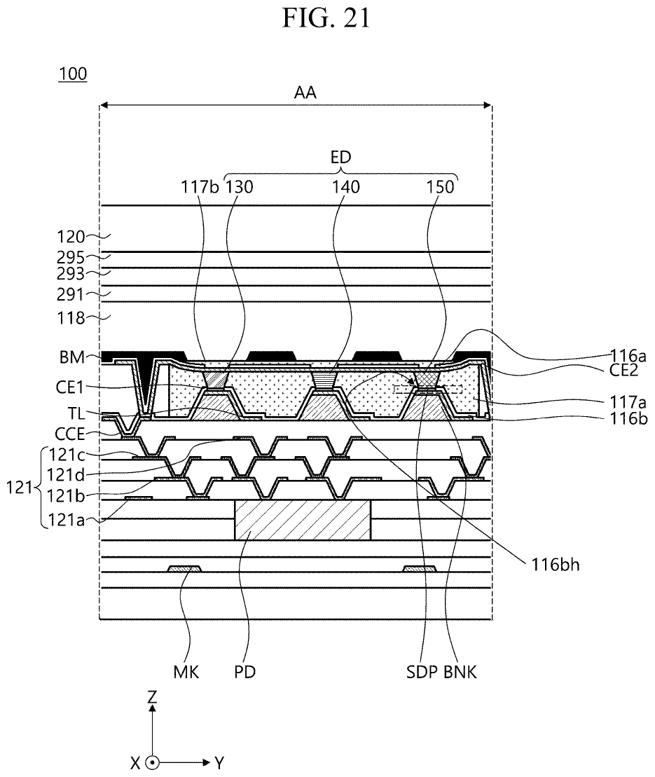

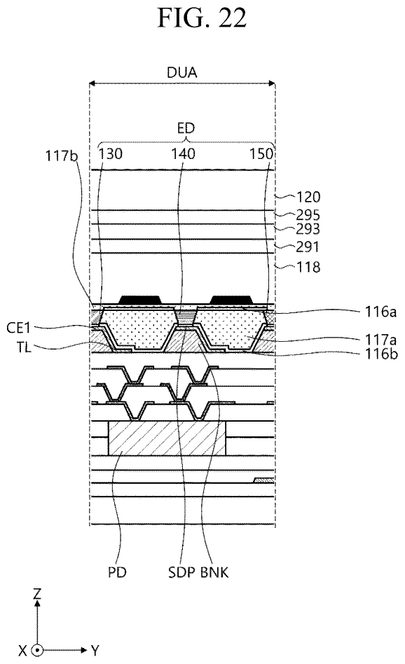

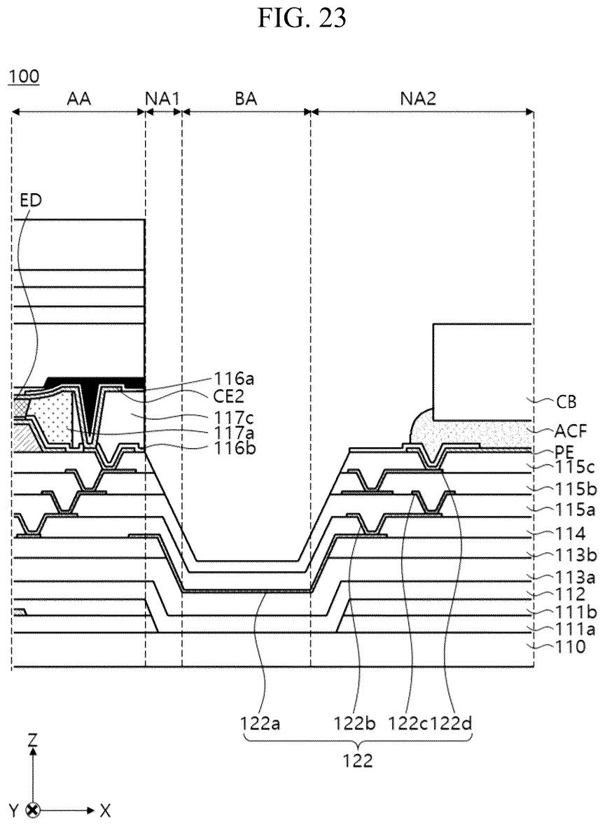

FIGS. 21 and 23 are cross-sectional views illustrating the display device according to the embodiment of the present specification. FIG. 22 is a cross-sectional view illustrating the display device according to the embodiment of the present specification.

FIGS. 21 and 23 are cross-sectional views of the display area AA, the first non-display area NA1, the bending area BA, and the second non-display area NA2.

FIG. 22 is a cross-sectional view of the dummy area DUA. The same reference numerals are assigned to configurations that perform substantially the same function in the cross-sectional views, and detailed descriptions thereof are omitted.

As shown in FIGS. 21, 22, and 23, a first buffer layer 111a and a second buffer layer 111b may be disposed in the remaining area of the substrate 110 excluding the bending area BA.

The first buffer layer 111a and the second buffer layer 111b may be disposed in the display area AA, the first non-display area NA1, and the second non-display area NA2. The first buffer layer 111a and the second buffer layer 111b may reduce the penetration of moisture or impurities through the substrate 110. The first buffer layer 111a and the second buffer layer 111b may be formed of an inorganic insulating material. For example, the first buffer layer 111a and the second buffer layer 111b may each be formed as a single layer or multiple layers of silicon oxide (SiOₓ) or silicon nitride (SiNₓ), but the embodiments of the present specification are not limited thereto.

For example, some of the first buffer layer 111a and the second buffer layer 111b located in the bending area BA may be removed. An upper surface of the substrate 110 located in the bending area BA may be exposed from the first buffer layer 111a and the second buffer layer 111b. The first buffer layer 111a and the second buffer layer 111b, which are formed of an inorganic insulating material, may be removed from the bending area BA to minimize or reduce cracks that may occur in the first buffer layer 111a and the second buffer layer 111b during bending.

A plurality of alignment keys MK may be disposed between the first buffer layer 111a and the second buffer layer 111b. The plurality of alignment keys MK may be configured to identify the position of the pixel driving circuit PD during the manufacturing process of the display device 1000. For example, the plurality of alignment keys MK may be configured to align the position of the pixel driving circuit PD that is transferred onto an adhesive layer 112. For another example, the plurality of alignment keys MK may be omitted.

The adhesive layer 112 may be disposed on the second buffer layer 111b. The adhesive layer 112 may be disposed in the display area AA, the first non-display area NA1, the bending area BA, and the second non-display area NA2. For another example, at least a portion of the adhesive layer 112 may be removed from the non-display area NA including the bending area BA. For example, the adhesive layer 112 may be formed of any one of an adhesive polymer, an epoxy resin, an ultraviolet (UV)-curable resin, a polyimide-based material, an acrylate-based material, a urethane-based material, and polydimethylsiloxane (PDMS), but the embodiments of the present specification are not limited thereto.

In the display area AA, the pixel driving circuit PD may be disposed on the adhesive layer 112. When the pixel driving circuit PD is implemented as a driving driver, the driving driver may be mounted on the adhesive layer 112 by a transfer process, but the embodiments of the present specification are not limited thereto.

A first protective layer 113a and a second protective layer 113b may be disposed on the adhesive layer 112 and the pixel driving circuit PD. The first protective layer 113a and the second protective layer 113b may be disposed to surround the side surfaces of the pixel driving circuit PD, but the embodiments of the present specification are not limited thereto. For example, the second protective layer 113b may be disposed to cover at least a portion of an upper surface of the pixel driving circuit PD. For example, at least one of the first protective layer 113a and the second protective layer 113b disposed in the bending area BA may be omitted. For example, the first protective layer 113a may be entirely disposed in the display area AA and the non-display area NA, and the second protective layer 113b may be partially disposed in the display area AA, the first non-display area NA1, and the second non-display area NA2. For example, a portion of the second protective layer 113b in the bending area BA may be removed. However, the embodiments of the present specification are not limited thereto.

The first protective layer 113a and the second protective layer 113b may be formed of an organic insulating material, but the embodiments of the present specification are not limited thereto. For example, the first protective layer 113a and the second protective layer 113b may be formed of photoresist, polyimide (PI), photo acrylic materials, or the like, but the embodiments of the present specification are not limited thereto. For example, the first protective layer 113a and the second protective layer 113b may each be an overcoating layer or an insulating layer, but the embodiments of the present specification are not limited thereto.

According to the present specification, a plurality of first connection lines 121 may be disposed on the second protective layer 113b in the display area AA. The plurality of first connection lines 121 may be lines for electrically connecting the pixel driving circuit PD to other components. For example, the pixel driving circuit PD may be electrically connected to the plurality of signal lines TL, the plurality of contact electrodes CCE, and the like through the plurality of first connection lines 121. For example, the plurality of first connection lines 121 may include a 1-1 connection line 121a, a 1-2 connection line 121b, a 1-3 connection line 121c, and a 1-4 connection line 121d, but the embodiments of the present specification are not limited thereto.

For example, a plurality of 1-1 connection lines 121a may be disposed on the second protective layer 113b. The plurality of 1-1 connection lines 121a may be electrically connected to the pixel driving circuit PD. The plurality of 1-1 connection lines 121a may transmit a voltage output from the pixel driving circuit PD to the first electrode CE1 or the second electrode CE2.

For example, a third protective layer 114 may be disposed on the second protective layer 113b. The third protective layer 114 may be entirely disposed in the display area AA and the non-display area NA. In the bending area BA, the third protective layer 114 may cover a side surface of the second protective layer 113b and an upper surface of the first protective layer 113a. The third protective layer 114 may be formed of an organic insulating material. For example, the third protective layer 114 may be formed of photoresist, polyimide (PI), photo acrylic materials, or the like, but the embodiments of the present specification are not limited thereto. For example, the first protective layer 113a, the second protective layer 113b, and the third protective layer 114 may be formed of the same material, but the embodiments of the present specification are not limited thereto.

A plurality of 1-2 connection lines 121b may be disposed on the third protective layer 114. The plurality of 1-2 connection lines 121b may be connected to or directly connected to the pixel driving circuit PD. For example, some of the 1-2 connection lines 121b may be directly connected to the pixel driving circuit PD through contact holes of the third protective layer 114. Another part of the 1-2 connection lines 121b may be electrically connected to the 1-1 connection line 121a through contact holes of the third protective layer 114. However, the embodiments of the present specification are not limited thereto. The voltage output from the pixel driving circuit PD may be transmitted to the first electrode CE1 or the second electrode CE2 through the plurality of 1-2 connection lines 121b and other connection lines.

A first insulating layer 115a may be disposed on the plurality of 1-2 connection lines 121b. The first insulating layer 115a may be entirely disposed in the display area AA and the non-display area NA, but the embodiments of the present specification are not limited thereto. The first insulating layer 115a may be formed of an organic insulating material, but the embodiments of the present specification are not limited thereto. For example, the first insulating layer 115a may be formed of photoresist, polyimide (PI), photo acrylic materials, or the like, but the embodiments of the present specification are not limited thereto.

A plurality of 1-3 connection lines 121c may be disposed on the first insulating layer 115a. The plurality of 1-3 connection lines 121c may be electrically connected to the plurality of 1-2 connection lines 121b. For example, the 1-3 connection lines 121c may be electrically connected to the 1-2 connection lines 121b through contact holes of the first insulating layer 115a.

A second insulating layer 115b may be disposed on the plurality of 1-3 connection lines 121c. The second insulating layer 115b may be disposed in the remaining area excluding the bending area BA, but the embodiments of the present specification are not limited thereto. The second insulating layer 115b may be disposed in the display area AA, the first non-display area NA1, and the second non-display area NA2, but the embodiments of the present specification are not limited thereto. For example, a portion of the second insulating layer 115b disposed in the bending area BA may be removed. The second insulating layer 115b may be formed of an organic insulating material, but the embodiments of the present specification are not limited thereto. For example, the second insulating layer 115b may be formed of photoresist, polyimide (PI), photo acrylic materials, or the like, but the embodiments of the present specification are not limited thereto.

A plurality of 1-4 connection lines 121d may be disposed on the second insulating layer 115b. The plurality of 1-4 connection lines 121d may be electrically connected to the plurality of 1-3 connection lines 121c. For example, the 1-4 connection lines 121d may be electrically connected to the 1-3 connection lines 121c through contact holes of the second insulating layer 115b.

According to the present specification, a plurality of second connection lines 122 may be disposed on the second protective layer 113b in the non-display area NA. The plurality of second connection lines 122 may be lines for transmitting signals, which are transmitted from the flexible circuit board (or flexible film) CB and the printed circuit board 160 (see FIG. 1) to the pad part PAD, to the pixel driving circuit PD of the display area AA. For example, the plurality of second connection lines 122 may be electrically connected to the plurality of pad electrodes PE to receive the signals output from the flexible circuit board (or flexible film) CB and the printed circuit board.

For example, the plurality of second connection lines 122 may extend from the pad part PAD toward the display area AA and may transmit signals to the lines of the display area AA. In this case, the plurality of second connection lines 122 may function as the link lines LL. The plurality of second connection lines 122 may include a 2-1 connection line 122a, a 2-2 connection line 122b, a 2-3 connection line 122c, and a 2-4 connection line 122d.

A plurality of 2-1 connection lines 122a may be disposed on the second protective layer 113b. The plurality of 2-1 connection lines 122a may extend from the second non-display area NA2 to the bending area BA and the first non-display area NA1. The plurality of 2-1 connection lines 122a may transmit signals, which are transmitted to the pad part PAD from the flexible circuit board (or flexible film) CB and the printed circuit board, to the pixel driving circuit PD of the display area AA.

A plurality of 2-2 connection lines 122b may be disposed on the third protective layer 114. The plurality of 2-2 connection lines 122b may be disposed in the second non-display area NA2. The 2-2 connection lines 122b may be electrically connected to the 2-1 connection lines 122a through contact holes of the third protective layer 114. Accordingly, the signals output from the flexible circuit board (or flexible film) CB and the printed circuit board may be transmitted to the 2-1 connection lines 122a through the 2-2 connection lines 122b.

The 2-3 connection line 122c may be disposed on the first insulating layer 115a. The 2-3 connection line 122c may be disposed in the second non-display area NA2. The 2-3 connection line 122c may be electrically connected to the 2-2 connection line 122b through a contact hole of the first insulating layer 115a. Accordingly, the signals output from the flexible circuit board (or flexible film) CB and the printed circuit board may be transmitted to the 2-1 connection lines 122a through the 2-3 connection line 122c and the 2-2 connection lines 122b.

The 2-4 connection line 122d may be disposed on the second insulating layer 115b. The 2-4 connection line 122d may be disposed in the second non-display area NA2. The 2-4 connection line 122d may be electrically connected to the 2-3 connection line 122c through the contact hole of the second insulating layer 115b. Accordingly, the signals output from flexible circuit board (or flexible film) CB and the printed circuit board may be transmitted to the 2-1 connection lines 122a through the 2-4 connection line 122d, the 2-3 connection line 122c, and the 2-2 connection lines 122b.

The plurality of first connection lines 121 and the plurality of second connection lines 122 may be formed of a highly flexible conductive material or any of the various conductive materials used in the display area AA. For example, the second connection lines 122, some of which are disposed in the bending area BA, may be formed of a highly flexible conductive material such as gold (Au), silver (Ag), or aluminum (Al), but the embodiments of the present specification are not limited thereto. For another example, the plurality of first connection lines 121 and the plurality of second connection lines 122 may be formed of molybdenum (Mo), chromium (Cr), titanium (Ti), nickel (Ni), neodymium (Nd), copper (Cu), an alloy of silver (Ag) and magnesium (Mg), alloys thereof, or the like, but the embodiments of the present specification are not limited thereto.

A third insulating layer 115c may be disposed on the plurality of first connection lines 121 and the plurality of second connection lines 122. The third insulating layer 115c may be disposed in the remaining area excluding the bending area BA, but the embodiments of the present specification are not limited thereto. The third insulating layer 115c may be disposed in the display area AA, the first non-display area NA1, and the second non-display area NA2. A portion of the third insulating layer 115c in the bending area BA may be removed. The third insulating layer 115c may be formed of an organic insulating material, but the embodiments of the present specification are not limited thereto. For example, the third insulating layer 115c may be formed of photoresist, polyimide (PI), photo acrylic materials, or the like, but the embodiments of the present specification are not limited thereto.

In the display area AA, a plurality of banks BNK may be disposed on the third insulating layer 115c. The plurality of banks BNK may be disposed to overlap the plurality of sub-pixels, respectively. At least one or more light-emitting elements ED of the same type may be disposed on each of the plurality of banks BNK.

A plurality of signal lines TL may be disposed on the third insulating layer 115c in the display area AA. The plurality of signal lines TL may be disposed in an area between the plurality of banks BNK. For example, the plurality of signal lines TL may be disposed adjacent to any one of the plurality of banks BNK.

A plurality of contact electrodes CCE may be disposed on the third insulating layer 115c in the display area AA. The plurality of contact electrodes CCE may supply a cathode voltage output from the pixel driving circuit PD to the second electrode CE2.

The first electrode CE1 may be disposed on the bank BNK. For example, the first electrode CE1 may be disposed to extend toward an upper portion of the bank BNK from the adjacent signal line TL. The first electrode CE1 may be disposed on upper and side surfaces of the bank BNK. For example, the first electrode CE1 may be disposed to extend from the signal line TL on an upper surface of the third insulating layer 115c to the side and upper surfaces of the bank BNK.

As shown in FIG. 22, the first electrode CE1 and the plurality of light-emitting elements 130, 140, and 150 may be disposed in the dummy area DUA. The second electrode CE2 may not be disposed in the dummy area. Accordingly, the cathode voltage is not supplied to the dummy area DUA through the second electrode, and the light-emitting elements 130, 140, and 150 do not emit light.

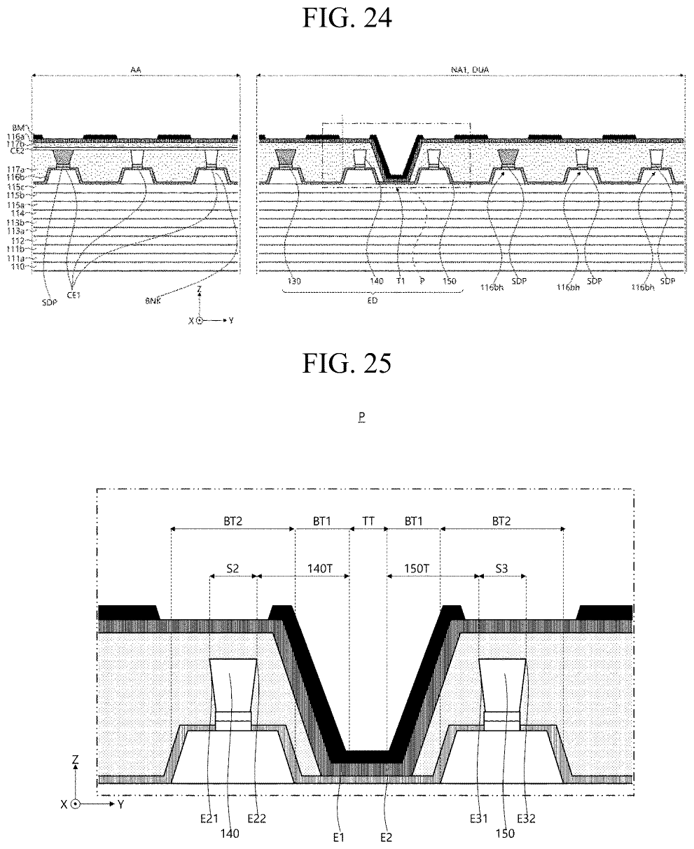

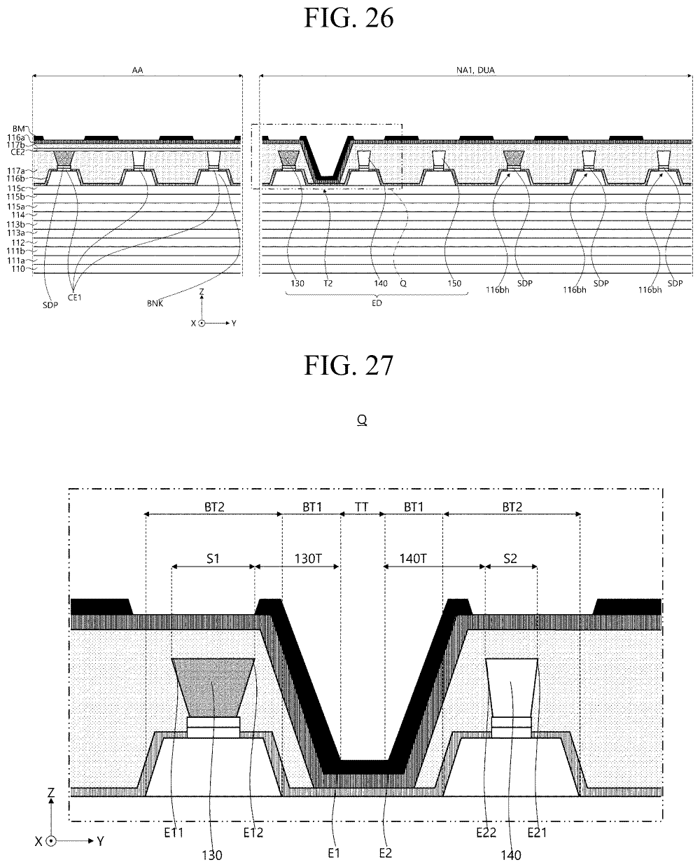

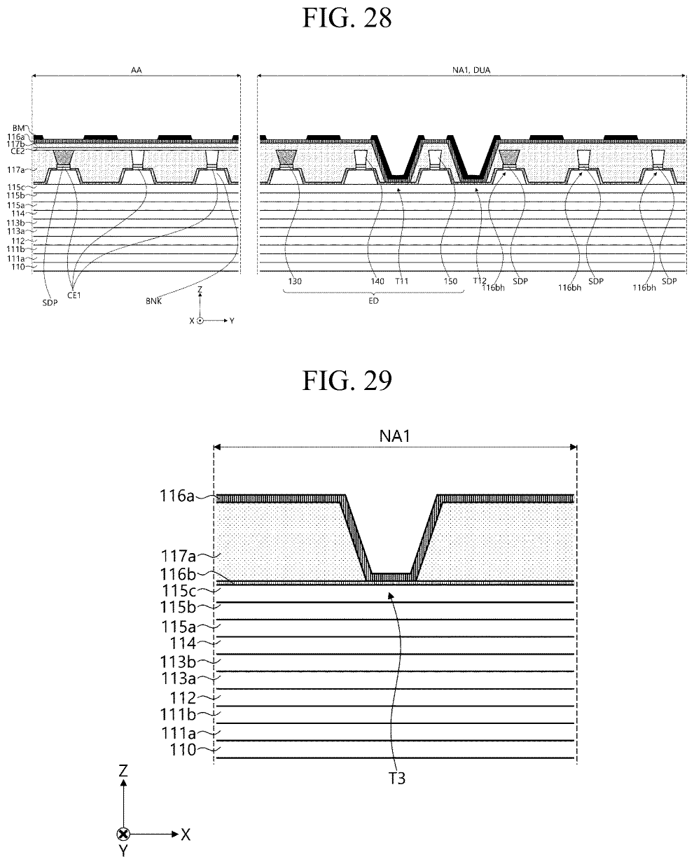

FIGS. 24 and 25 are cross-sectional views illustrating a display device according to an embodiment of the present specification. FIGS. 26 and 27 are cross-sectional views illustrating a display device according to a first comparative example with respect to FIG. 24. FIGS. 28 and 29 are cross-sectional views illustrating the display device according to the embodiment of the present specification.

The same reference numerals are assigned to configurations that perform substantially the same function in the above-described embodiments or comparative examples, or the cross-sectional views, and detailed descriptions thereof are omitted.

FIG. 24 is a cross-sectional view corresponding to the display device according to the first embodiment. FIG. 25 is a partially enlarged view illustrating portion P of FIG. 24.

As shown in FIGS. 24 and 25, the display device may include a plurality of light-emitting elements 130, 140, and 150 disposed in the display area AA and the first non-display area NA1. First optical layers 117a may be disposed between the plurality of light-emitting elements 130, 140, and 150. The first optical layers 117a may surround the plurality of light-emitting elements 130, 140, and 150. A second optical layer 117b may be disposed on the first optical layer 117a. The second optical layer 117b may be disposed in the display area AA and the dummy area DUA. In the first non-display area NA1, an area in which the second optical layer 117b is not disposed may have a smaller thickness (for example, a length in the Z-axis direction) formed by the optical layer than that formed by the optical layer in the dummy area DUA.

A first passivation layer 116a may be disposed on the first optical layer 117a. The first passivation layer 116a may be disposed on the second optical layer 117b. The first passivation layer 116a may be formed in at least some of the display area AA and the first non-display area NA1. The first passivation layer 116a may be formed on the first optical layer 117a and/or the second optical layer 117b to entirely cover the display area AA and the first non-display area NA1. The first optical layer 117a and/or the second optical layer 117b may be protected by the first passivation layer 116a. For example, the reliability of the display device can be improved by protecting the display device from moisture penetration from the outside.

A second passivation layer 116b may be formed to cover banks BNK on which the plurality of light-emitting elements 130, 140, and 150 are disposed. The second passivation layer 116b may include a hole 116bh that exposes a solder pattern SDP. The display device according to the embodiment of the present specification may further include the first passivation layer 116a that protects the first optical layer 117a and/or the second optical layer 117b, in addition to the second passivation layer 116b that protects a lower portion of the bank BNK, thereby extending the lifespan of the display device.

The display device may include a first trench T1. With reference to the coordinate system, the first trench T1 may be disposed to extend in the first direction (for example, the X-axis direction). The first non-display area NA1 may include the first trench T1. The dummy area DUA may include the first trench T1. The first trench T1 may be formed between the plurality of light-emitting elements 130, 140, and 150. The first trench T1 may be formed between the plurality of dummy light-emitting elements (the plurality of light-emitting elements disposed in the dummy area DUA).

The first optical layer 117a formed in the first non-display area NA1 and/or the dummy area DUA may include the first trench T1. The second optical layer 117b formed in the first non-display area NA1 and/or the dummy area DUA may include the first trench T1. The first trench T1 may be formed by removing at least some of the first optical layer 117a and/or the second optical layer 117b. The first passivation layer 116a may be disposed in the first trench T1. At least a portion of a black matrix BM may be disposed in the first trench T1.

As shown in FIG. 25, the first trench T1 may include a first end E1 and a second end E2 facing each other. The second light-emitting element 140 may include a 2-1 end E21 relatively far from the first end E1 and a 2-2 end E22 relatively close to the first end E1. The third light-emitting element 150 may include a 3-1 end E31 relatively close to the second end E2 and a 3-2 end E32 relatively far from the second end E2.

FIG. 26 is a cross-sectional view corresponding to the display device according to the first comparative example. FIG. 27 is a partially enlarged view illustrating portion Q of FIG. 26.

As shown in FIG. 27, the first trench T1 may include a first end E1 and a second end E2 facing each other. The first light-emitting element 130 may include a 1-1 end E11 relatively far from the first end E1 and a 1-2 end E12 relatively close to the first end E1. The second light-emitting element 140 may include a 2-1 end E21 relatively far from the second end E2 and a 2-2 end E22 relatively close to the second end E2.

The relationships among the various ends and the distances between the ends, as defined in the cross-sectional views according to the embodiments and comparative examples, have already been described above with reference to FIGS. 7 to 10.

FIG. 28 is a cross-sectional view corresponding to the display device according to the second modified example of the first embodiment. FIG. 29 is a cross-sectional view corresponding to the display device according to the third embodiment. The same reference numerals are assigned to configurations that perform substantially the same function in the above-described embodiments, and detailed descriptions are omitted.

As shown in FIG. 28, the display device may include a plurality of trenches T11 and T12. The display device may include an 1-1 trench T11 disposed between the second light-emitting element 140 and the third light-emitting element 150, and a 1-2 trench T12 disposed between the third light-emitting element 150 and the first light-emitting element 130.

As shown in FIG. 29, the display device may include a first optical layer 117a. A third trench T3 may be formed by removing at least a portion of the first optical layer 117a. As shown in the plan view corresponding to a third example embodiment, the light-emitting elements may not be disposed between the bending area and the third trench T3. Further, since an area in which the second optical layer extends is substantially the same as an area in which the second electrode extends, the display device may not include the second optical layer. Thus, the thickness (e.g., the length in the Z-axis direction) of the area in which the second optical layer is not formed may be less than that of the area in which the second optical layer is formed.

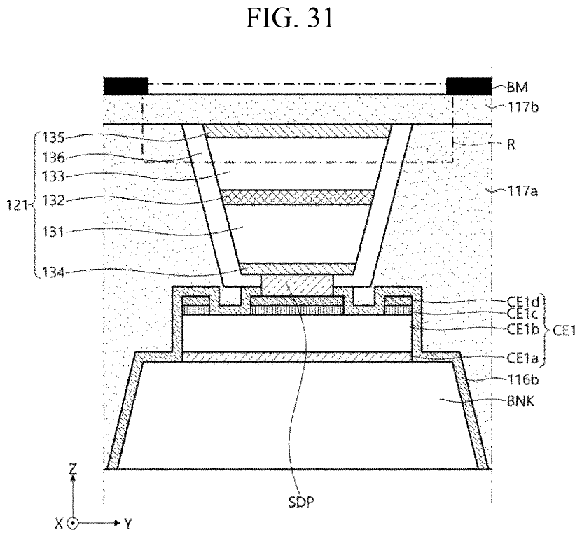

FIG. 30 is a cross-sectional view illustrating a display device according to an example embodiment of the present specification. FIG. 31 is a cross-sectional view illustrating the display device according to the embodiment of the present specification.

FIG. 30 is a cross-sectional view illustrating a sub-pixel including a light-emitting element disposed in the display area AA.

FIG. 31 is a cross-sectional view illustrating a sub-pixel including a light-emitting element disposed in the dummy area DUA. The same reference numerals are assigned to configurations that perform substantially the same function in the cross-sectional views, and detailed descriptions thereof are omitted.

As shown in FIGS. 30 and 31, the first electrode CE1 may be composed of a plurality of conductive layers. For example, the first electrode CE1 may include a first conductive layer CE1a, a second conductive layer CE1b, a third conductive layer CE1c, and a fourth conductive layer CE1d, but the embodiments of the present specification are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b. The fourth conductive layer CE1d may be disposed on the third conductive layer CE1c. For example, the first conductive layer CE1a, the second conductive layer CE1b, the third conductive layer CE1c, and the fourth conductive layer CE1d may each be formed of titanium (Ti), molybdenum (Mo), aluminum (Al), or titanium (Ti) and indium tin oxide (ITO), but the embodiments of the present specification are not limited thereto.

According to the present specification, among the plurality of conductive layers forming the first electrode CE1, some conductive layers with high reflectivity may be configured as alignment keys and/or reflectors for the alignment of the light-emitting element ED. For example, among the plurality of conductive layers of the first electrode CE1, the second conductive layer CE1b may include a reflective material. For example, the second conductive layer CE1b may include aluminum (Al), but the embodiments of the present specification are not limited thereto. Accordingly, the second conductive layer CE1b may be configured as a reflector. Further, due to the high reflectivity of the second conductive layer CE1b, identification may be facilitated in the manufacturing process, thereby allowing the position or transfer position of the light-emitting element ED to be aligned based on the second conductive layer CE1b.

For example, to configure the second conductive layer CE1b as a reflector, the third conductive layer CE1c and the fourth conductive layer CE1d covering the second conductive layer CE1b may be partially removed or etched. For example, some of the third conductive layer CE1c and the fourth conductive layer CE1d disposed on the bank BNK may be removed or etched to expose an upper surface of the second conductive layer CE1b. For example, in each of the third conductive layer CE1c and the fourth conductive layer CE1d, a central portion on which the solder pattern SDP is disposed and edge portions may be retained, whereas the remaining portions may be removed. For example, the edge portions of each of the third conductive layer CE1c, which is formed of titanium (Ti), and the fourth conductive layer CE1d, which is formed of indium tin oxide (ITO), may not be etched. Accordingly, it is possible to prevent or suppress other conductive layers of the first electrode CE1 from being corroded by a tetramethylammonium hydroxide (TMAH) solution used in the masking process of the first electrode CE1.

According to the present specification, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer, such as indium tin oxide (ITO) or indium zinc oxide (IZO), which has good adhesion to the solder pattern SDP and exhibits corrosion resistance and acid resistance. However, the embodiments of the present specification are not limited thereto.

The first conductive layer CE1a, the second conductive layer CE1b, the third conductive layer CE1c, and the fourth conductive layer CE1d may be sequentially deposited and then patterned through a photolithography process and an etching process, but the embodiments of the present specification are not limited thereto.

According to the present specification, the signal line TL, contact electrode CCE, and pad electrode PE, which are disposed on the same layer as the first electrode CE1, may be formed as multiple layers of conductive materials, but the embodiments of the present specification are not limited thereto. For example, the signal line TL, the contact electrode CCE, and the pad electrode PE may be formed as multiple layers of indium tin oxide (ITO)/titanium (Ti)/aluminum (A1)/titanium (Ti), but the embodiments of the present specification are not limited thereto.

According to the present specification, the solder pattern SDP may be disposed on the first electrode CE1 in each of the plurality of sub-pixels. The solder pattern SDP may bond the light-emitting element ED to the first electrode CE1. The first electrode CE1 and the light-emitting element ED may be electrically connected through eutectic bonding using the solder pattern SDP, but the embodiments of the present specification are not limited thereto. For example, when the solder pattern SDP is formed of indium (In) and the anode 134 of the light-emitting element ED is formed of gold (Au), the solder pattern SDP and the anode 134 may be bonded by applying heat and pressure during the transfer process of the light-emitting element ED. Through eutectic bonding, the light-emitting element ED may be bonded to the solder pattern SDP and the first electrode CE1 without any additional adhesive. For example, the solder pattern SDP may be formed of indium (In), tin (Sn), or an alloy thereof, but the embodiments of the present specification are not limited thereto. For example, the solder pattern SDP may be a bonding pad, a joining pad, or the like, but the embodiments of the present specification are not limited thereto.

According to the present specification, the second passivation layer 116b may be disposed on the plurality of signal lines TL, the plurality of first electrodes CE1, a plurality of contact electrodes CCE, and the third insulating layer 115c. For example, the second passivation layer 116b may be disposed in the display area AA, the first non-display area NA1, and the second non-display area NA2. A portion of the second passivation layer 116b disposed in the bending area BA may be removed. In the second non-display area NA2, a portion of the second passivation layer 116b covering the plurality of pad electrodes PE may be removed. The second passivation layer 116b is disposed to cover the remaining areas except for the bending area BA and the area in which the plurality of pad electrodes PE and the solder pattern SDP are disposed, thereby reducing the penetration of moisture or impurities into the light-emitting element ED. For example, the second passivation layer 116b may be formed as a single layer or multiple layers of silicon oxide (SiOₓ) or silicon nitride (SiNₓ), but the embodiments of the present specification are not limited thereto. For example, the second passivation layer 116b may be a protective layer, an insulating layer, or the like, but the embodiments of the present specification are not limited thereto. For example, the second passivation layer 116b may include a hole 116bh that exposes the solder pattern SDP.

In each of the plurality of sub-pixels, the light-emitting element ED may be disposed on the solder pattern SDP. In the first sub-pixel SP1, the first light-emitting element 130 may be disposed. In the second sub-pixel SP2, the second light-emitting element 140 may be disposed. The third light-emitting element 150 may be disposed in the third sub-pixel SP3.

The light-emitting element ED may be formed on a silicon wafer using methods such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering, but the embodiments of the present specification are not limited thereto.

As shown in FIGS. 30 and 31, the first light-emitting element 130 may include an anode 134, a first semiconductor layer 131, an active layer 132, a second semiconductor layer 133, a cathode 135, and an encapsulation film 136, but the embodiments of the present specification are not limited thereto. For example, the first light-emitting element 130 may not include the encapsulation film 136.

The first semiconductor layer 131 may be disposed on the solder pattern SDP. The second semiconductor layer 133 may be disposed on the first semiconductor layer 131.

For example, one of the first semiconductor layer 131 and the second semiconductor layer 133 may be implemented as a group III-V compound semiconductor, a group II-VI compound semiconductor, or the like and may be doped with impurities (or dopants). For example, one of the first semiconductor layer 131 and the second semiconductor layer 133 may be a semiconductor layer doped with n-type impurities, and the other may be a semiconductor layer doped with p-type impurities, but the embodiments of the present specification are not limited thereto. For example, one or more of the first semiconductor layer 131 and the second semiconductor layer 133 may be a layer doped with n-type or p-type impurities in a material such as gallium nitride (GaN), gallium phosphide (GaP), gallium arsenide phosphide (GaAsP), aluminum gallium indium phosphide (AlGaInP), indium aluminum phosphide (InAIP), aluminum gallium nitride (AlGaN), aluminum indium nitride (AlInN), aluminum indium gallium nitride (AlInGaN), aluminum gallium arsenide (AlGaAs), gallium arsenide (GaAs), or the like, but the embodiments of the present specification are not limited thereto. For example, the n-type impurities may include silicon (Si), germanium (Ge), selenium (Se), carbon (C), tellurium (Te), tin (Sn), and the like, but the embodiments of the present specification are not limited thereto. For example, the p-type impurities may include magnesium (Mg), zinc (Zn), calcium (Ca), strontium (Sr), barium (Ba), beryllium (Be), and the like, but the embodiments of the present specification are not limited thereto.

For example, the first semiconductor layer 131 and the second semiconductor layer 133 may be a nitride semiconductor containing n-type impurities and a nitride semiconductor containing p-type impurities, respectively, but the embodiments of the present specification are not limited thereto. For example, the first semiconductor layer 131 may be a nitride semiconductor containing p-type impurities, and the second semiconductor layer 133 may be a nitride semiconductor containing n-type impurities, but the embodiments of the present specification are not limited thereto.

The active layer 132 may be disposed between the first semiconductor layer 131 and the second semiconductor layer 133. The active layer 132 may emit light by receiving holes and electrons from the first semiconductor layer 131 and the second semiconductor layer 133. For example, the active layer 132 may include one of a single well structure, a multi-well structure, a single quantum well structure, a multi-quantum well (MQW) structure, a quantum dot structure, and a quantum wire structure, but the embodiments of the present specification are not limited thereto. For example, the active layer 132 may be formed of indium gallium nitride (InGaN), gallium nitride (GaN), or the like, but the embodiments of the present specification are not limited thereto.

For another example, the active layer 132 may include a multi-quantum well (MQW) structure having a well layer and a barrier layer with a higher bandgap than the well layer. For example, the active layer 132 may include an InGaN well layer and an AlGaN barrier layer, but the embodiments of the present specification are not limited thereto.

The anode 134 may be disposed between the first semiconductor layer 131 and the solder pattern SDP. For example, the anode 134 may electrically connect the first semiconductor layer 131 and the first electrode CE1. An anode voltage output from the pixel driving circuit PD may be applied to the first semiconductor layer 131 through the signal line TL, the first electrode CE1, and the anode 134. For example, the anode 134 may be formed of a conductive material capable of eutectic bonding with the solder pattern SDP, but the embodiments of the present specification are not limited thereto. For example, the anode 134 may be formed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), copper (Cu), or an alloy thereof, but the embodiments of the present specification are not limited thereto.

The cathode 135 may be disposed on the second semiconductor layer 133. For example, the cathode 135 may electrically connect the second semiconductor layer 133 and the second electrode CE2. A cathode voltage output from the pixel driving circuit PD may be applied to the second semiconductor layer 133 through the contact electrode CCE, the second electrode CE2, and the cathode 135. The cathode 135 may be formed of a transparent conductive material to allow light emitted from the light-emitting element ED to be directed upward, but the embodiments of the present specification are not limited thereto. For example, the cathode 135 may be formed of a material such as indium tin oxide (ITO), indium zinc oxide (IZO), or indium gallium zinc oxide (IGZO), but the embodiments of the present specification are not limited thereto.

The encapsulation film 136 may be disposed on at least some of the first semiconductor layer 131, the active layer 132, the second semiconductor layer 133, the anode 134, and the cathode 135. For example, the encapsulation film 136 may surround at least some of the first semiconductor layer 131, the active layer 132, the second semiconductor layer 133, the anode 134, and the cathode 135.

For example, the encapsulation film 136 may protect the first semiconductor layer 131, the active layer 132, and the second semiconductor layer 133. For example, the encapsulation film 136 may be disposed on the side surfaces of the first semiconductor layer 131, the active layer 132, and the second semiconductor layer 133.

For example, the encapsulation layer 136 may be disposed on at least a portion of each of the anode 134 and the cathode 135, for example, on an edge portion (or one side) of the anode 134 and an edge portion (or one side) of the cathode 135. At least a portion of the anode 134 may be exposed from the encapsulation film 136, thereby allowing the anode 134 to be connected to the solder pattern SDP. For example, at least a portion of the cathode 135 may be exposed from the encapsulation film 136, thereby allowing the cathode 135 to be connected to the second electrode CE2. For example, the encapsulation film 136 may be formed of an insulating material such as silicon nitride (SiNₓ) or silicon oxide (SiOₓ), but the embodiments of the present specification are not limited thereto.

For another example, the encapsulation film 136 may have a structure in which a reflective material is dispersed in a resin layer, but the embodiments of the present specification are not limited thereto. For example, the encapsulation film 136 may be fabricated as a reflector with various structures, but the embodiments of the present specification are not limited thereto. Light emitted from the active layer 132 may be reflected upward by the encapsulation film 136, thereby enhancing light extraction efficiency. For example, the encapsulation film 136 may be a reflective layer, but the embodiments of the present specification are not limited thereto.

According to the present specification, the light-emitting element ED has been described as having a vertical structure, but the embodiments of the present specification are not limited thereto. For example, the light-emitting element ED may have a lateral structure or a flip chip structure.

Although the first light-emitting element 130 has been described with reference to FIGS. 30 and 31, but the second light-emitting element 140 and the third light-emitting element 150 may have substantially the same structure as the first light-emitting element 130. For example, the second light-emitting element 140 and the third light-emitting element 150 may be substantially the same structure as the first semiconductor layer 131, the active layer 132, the second semiconductor layer 133, the anode 134, the cathode 135, and the encapsulation film 136 of the first light-emitting element 130.

As shown in FIG. 31, the first electrode CE1 and a plurality of light-emitting elements may be disposed in the dummy area. In the dummy area, the second electrode CE2 may not be disposed. Accordingly, the cathode voltage is not supplied to the dummy area through the second electrode, and the light-emitting elements do not emit light.

Referring again to FIGS. 21, 22, and 23, the first optical layers 117a surrounding the plurality of light-emitting elements ED in the display area AA may be disposed. For example, the first optical layers 117a may be disposed to cover the plurality of light-emitting elements ED and the banks BNK in the areas of the plurality of sub-pixels. For example, the first optical layers 117a may cover the banks BNK, a portion of the second passivation layer 116b, and spaces between the plurality of light-emitting elements ED. The first optical layers 117a may be disposed in or may cover the spaces between the plurality of light-emitting elements ED included in one pixel PX and between the plurality of banks BNK. For example, the first optical layers 117a may extend in the first direction X and may be disposed spaced apart in the second direction Y. For example, the first optical layer 117a may be disposed to surround the side portions of the light-emitting element ED and the bank BNK between the second passivation layer 116b and the second electrode CE2, but the embodiments of the present specification are not limited thereto. For example, the first optical layer 117a may be a diffusion layer, a sidewall diffusion layer, or the like, but the embodiments of the present specification are not limited thereto.

The first optical layer 117a may include an organic insulating material in which fine particles are dispersed, but the embodiments of the present specification are not limited thereto. For example, the first optical layer 117a may be formed of siloxane in which fine metal particles, such as titanium dioxide (TiO₂) particles, are dispersed, but the embodiments of the present specification are not limited thereto. Light emitted from the plurality of light-emitting elements ED may be scattered by the fine particles dispersed in the first optical layer 117a and emitted to the outside of the display device 1000. Accordingly, the first optical layer 117a may improve the extraction efficiency of the light emitted from the plurality of light-emitting elements ED.

For example, the first optical layer 117a may be disposed in each of the plurality of pixels PX, or the first optical layers 117a may be disposed together with some of the pixels PX disposed in the same row, but the embodiments of the present specification are not limited thereto. For example, the first optical layer 117a may be disposed in each of the plurality of pixels PX, or the plurality of pixels PX may share one first optical layer 117a. For another example, each of the plurality of sub-pixels may separately include the first optical layer 117a, but the embodiments of the present specification are not limited thereto.

According to the present specification, the third optical layer 117c may be disposed on the second passivation layer 116b in the display area AA. For example, the third optical layer 117c may be disposed to surround the first optical layer 117a. For example, the third optical layer 117c may be in contact with a side surface of the first optical layer 117a. For example, the third optical layer 117c may be disposed in areas between the plurality of pixels PX. However, the embodiments of the present specification are not limited thereto. For example, the third optical layer 117c may be a diffusion layer, a diffusion layer window, a window diffusion layer, or the like, but the embodiments of the present specification are not limited thereto.

The third optical layer 117c may be formed of an organic insulating material, but the embodiments of the present specification are not limited thereto. The third optical layer 117c may be formed of the same material as the first optical layer 117a, but the embodiments of the present specification are not limited thereto. For example, the first optical layer 117a may include fine particles, and the third optical layer 117c may not include fine particles. For example, the third optical layer 117c may be formed of siloxane, but the embodiments of the present specification are not limited thereto.

For example, a thickness of the first optical layer 117a may be less than a thickness of the third optical layer 117c, but the embodiments of the present specification are not limited thereto. Accordingly, when viewed in a plan view, an area in which the first optical layer 117a is disposed may include a recessed portion that is recessed inward relative to an upper surface of the third optical layer 117c.

According to the present specification, the second electrode CE2 may be disposed on the first optical layer 117a and the third optical layer 117c. For example, the second electrode CE2 may be electrically connected to the plurality of contact electrodes CCE through a contact hole of the third optical layer 117c. For example, the second electrode CE2 may be disposed on the plurality of light-emitting elements ED. For example, the second electrode CE2 may include a transparent conductive oxide such as indium tin oxide (ITO) or indium zinc oxide (IZO), but the embodiments of the present specification are not limited thereto. For example, the second electrode CE2 may be disposed to be in contact with the cathode 135. For example, the second electrode CE2 may overlap the first optical layer 117a. For example, the second electrode CE2 may cover a plane on an outer side of the first optical layer 117a.

The second electrode CE2 may continuously extend in the first direction X of the substrate 110. Accordingly, the second electrode CE2 may be commonly connected to the plurality of pixels PX arranged in the first direction X of the substrate 110. For example, the second electrode CE2 may be commonly connected to a plurality of pixels PX.

According to the present specification, the second electrode CE2 may continuously extend on the first optical layer 117a, the third optical layer 117c, and the light-emitting element ED. The area in which the first optical layer 117a is disposed may include a recessed portion that is recessed inward relative to the upper surface of the third optical layer 117c. Accordingly, since a first portion of the second electrode CE2 disposed on the first optical layer 117a is disposed along the recessed portion, the first portion of the second electrode CE2 may be disposed at a position lower than that of a second portion of the second electrode CE2 disposed on the third optical layer 117c.

The second optical layer 117b may be disposed on the second electrode CE2. The second optical layer 117b may be disposed to overlap the plurality of light-emitting elements ED and the first optical layer 117a. Since the second optical layer 117b is disposed on the second electrode CE2 and the plurality of light-emitting elements ED, the second optical layer 117b may improve the mura that may occur in some of the plurality of light-emitting elements ED. For example, when transferring the plurality of light-emitting elements ED onto the substrate 110 of the display device 1000, an area in which intervals between the plurality of light-emitting elements ED are not uniform may occur due to process variations or the like. When the intervals between the plurality of light-emitting elements ED are not uniform, light emission areas of each of the plurality of light-emitting elements ED may be disposed unevenly, which may cause a user to perceive mura. Accordingly, by configuring the second optical layer 117b to uniformly diffuse light over the plurality of light-emitting elements ED, the occurrence of light emitted from some light-emitting elements ED appearing as mura can be reduced. Accordingly, the light emitted from the plurality of light-emitting elements ED is evenly diffused by the second optical layer 117b and extracted to the outside of the display device 1000, thereby improving the luminance uniformity of the display device 1000.

The second optical layer 117b may be formed of an organic insulating material in which fine particles are dispersed, but the embodiments of the present specification are not limited thereto. For example, the second optical layer 117b may be formed of siloxane in which fine metal particles such as titanium dioxide (TiO₂) particles are dispersed, but the embodiments of the present specification are not limited thereto. For example, the second optical layer 117b may be formed of the same material as the first optical layer 117a, but the embodiments of the present specification are not limited thereto. For example, the second optical layer 117b may be a diffusion layer, an upper diffusion layer, or the like, but the embodiments of the present specification are not limited thereto.

According to the present specification, light emitted from the plurality of light-emitting elements ED may be scattered by the fine particles dispersed in the second optical layer 117b and emitted to the outside of the display device 1000. The second optical layer 117b may evenly mix the light emitted from the plurality of light-emitting elements ED, thereby further improving the luminance uniformity of the display device 1000. In addition, the light extraction efficiency of the display device 1000 may be improved by the light scattered from the plurality of fine particles, thereby enabling the display device 1000 to operate at lower power.

According to the present specification, the first passivation layer 116a may be disposed on the first optical layer 117a. Alternatively, the first passivation layer 116a may be disposed on the second optical layer 117b. Alternatively, the first passivation layer 116a may be disposed on the third optical layer 117c. For example, the first passivation layer 116a may be disposed in the display area AA and the first non-display area NA1. The first passivation layer 116a is disposed to cover the first optical layer 117a, the second optical layer 117b, or the third optical layer 117c disposed in the display area AA and the first non-display area NA1, thereby reducing the penetration of moisture or impurities into the first optical layer 117a, the second optical layer 117b, or the third optical layer 117c. For example, the second passivation layer 116b may be formed as a single layer or multiple layers of silicon oxide (SiOₓ) or silicon nitride (SiNₓ), but the embodiments of the present specification are not limited thereto. For example, the first passivation layer 116a may be a protective layer, an insulating layer, or the like, but the embodiments of the present specification are not limited thereto.

In the display area AA, the black matrix BM may be disposed on the second electrode CE2, the first optical layer 117a, the third optical layer 117c, and the second optical layer 117b. For example, the contact hole of the third optical layer 117c may be filled with the black matrix BM. The black matrix BM is configured to cover the display area AA, and thus may reduce the color mixing of light from the plurality of sub-pixels and the reflection of external light. For example, the black matrix BM is disposed in a contact hole in which the second electrode CE2 and the contact electrode CCE are connected, and thus may prevent or suppress light leakage between the plurality of adjacent sub-pixels.

For example, the black matrix BM may be formed of an opaque material, but the embodiments of the present specification are not limited thereto. For example, the black matrix BM may be an organic insulating material containing a black pigment or a black dye, but the embodiments of the present specification are not limited thereto.

In the display area AA, a cover layer 118 may be disposed on the black matrix BM. The cover layer 118 may protect the configuration below the cover layer 118, and for example, the cover layer 118 may be formed of an organic insulating material, but the embodiments of the present specification are not limited thereto. For example, the cover layer 118 may be formed of photoresist, polyimide (PI), photo acrylic materials, or the like, but the embodiments of the present specification are not limited thereto. For example, the cover layer 118 may be an overcoating layer, an insulating layer, or the like, but the embodiments of the present specification are not limited thereto.

The polarizing layer 293 may be disposed on the cover layer 118 through a first adhesive layer 291. The cover member 120 may be disposed on the polarizing layer 293 through the second adhesive layer 295. For example, the first adhesive layer 291 and the second adhesive layer 295 may include an optically clear adhesive (OCA), optically clear resin (OCR), pressure sensitive adhesive (PSA), or the like, but the embodiments of the present specification are not limited thereto.

According to the present specification, a plurality of pad electrodes PE may be disposed on the third insulating layer 115c in the second non-display area NA2. For example, at least some of the plurality of pad electrodes PE may be exposed from the second passivation layer 116b. For example, the plurality of pad electrodes PE may be electrically connected to the 2-4 connection line 122d through contact holes of the third insulating layer 115c.

A conductive adhesive layer ACF may be disposed on the plurality of pad electrodes PE. The conductive adhesive layer ACF may be an adhesive layer in which conductive balls are dispersed in an insulating material, but the embodiments of the present specification are not limited thereto. When heat or pressure is applied to the conductive adhesive layer ACF, the conductive balls at the portions to which the heat or pressure is applied may become electrically connected, thereby exhibiting conductive properties. The conductive adhesive layer ACF may be disposed between the plurality of pad electrodes PE and the flexible circuit board (or flexible film) CB, thereby allowing the flexible circuit board (or flexible film) CB to be attached or bonded to the plurality of pad electrodes PE. For example, the conductive adhesive layer ACF may be an anisotropic conductive film (ACF), but the embodiments of the present specification are not limited thereto.

The flexible circuit board (or flexible film) CB may be disposed on the conductive adhesive layer ACF. The flexible circuit board (or flexible film) CB may be electrically connected to the plurality of pad electrodes PE through the conductive adhesive layer ACF. Accordingly, signals output from the flexible circuit board (or flexible film) CB and the printed circuit board may be transmitted to the pixel driving circuit PD of the display area AA through the plurality of pad electrodes PE, and the 2-4 connection line 122d, the 2-3 connection line 122c, the 2-2 connection line 122b, and the 2-1 connection line 122a.

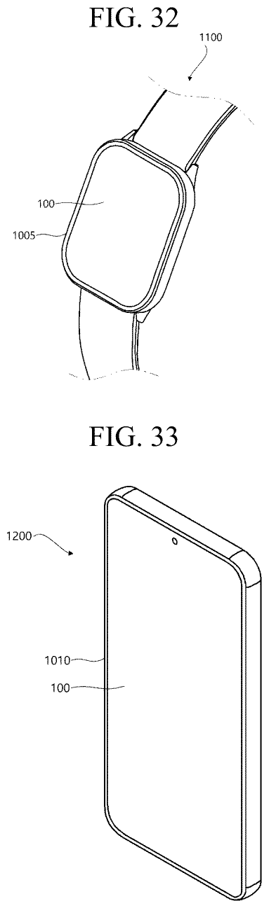

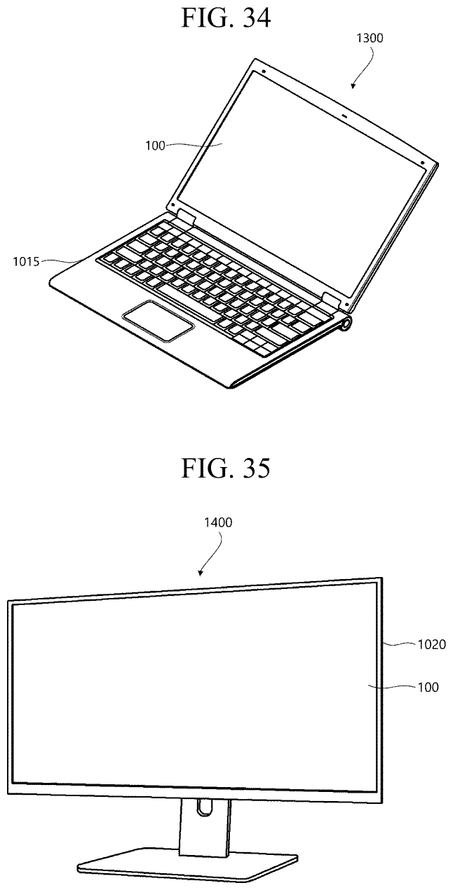

FIGS. 32 to 35 are views illustrating devices to which the display device according to example embodiments of the present specification is applied.

As shown in FIGS. 32 to 35, the display device 1000 according to example embodiments of the present specification may be included in various devices or electronic devices. For example, as shown in FIGS. 32 to 35, the various electronic devices may include a wearable device 1100, a mobile device 1200, a laptop 1300, and a monitor or TV 1400, but the embodiments of the present specification are not limited thereto.

The wearable device 1100, the mobile device 1200, the laptop 1300, and the monitor or TV 1400 may include case parts 1005, 1010, 1015, and 1020, respectively, and may each include the display panel 100 and the display device 1000 according to the embodiments of the present specification described above.

For example, the display device according to example embodiments of the present specification may be applied to mobile devices, video phones, smart watches, watch phones, wearable apparatuses, foldable apparatuses, rollable apparatuses, bendable apparatuses, flexible apparatuses, curved apparatuses, sliding apparatuses, variable apparatuses, electronic organizers, e-books, portable multimedia players (PMPs), personal digital assistants (PDAs), MP3 players, mobile medical devices, desktop personal computers (PCs) s, laptop PCs, netbook computers, workstations, navigation devices, vehicle display devices, theater display devices, televisions, wallpaper devices, signage devices, gaming devices, laptops, monitors, cameras, camcorders, household appliances, and the like.

The display panel and the display device including the same according to one or more embodiments of the present specification may be described as follows.

A display panel according to an embodiment of the present specification may include a first light-emitting element having a first size and implementing a first color, a second light-emitting element having a second size different from the first size and implementing a second color, a third light-emitting element having a third size different from the first size and implementing a third color, and a trench formed between the second light-emitting element and the third light-emitting element.

In the display panel according to the embodiment, the second size and the third size may be substantially the same.

In the display panel according to the embodiment, the first size may be greater than each of the second size and the third size.

In the display panel according to the embodiment, the trench may include a first end and a second end facing each other, the first light-emitting element may include a 1-1 end relatively far from the first end and a 1-2 end relatively close to the first end, the second light-emitting element may include a 2-1 end relatively far from the first end and a 2-2 end relatively close to the first end, and the third light-emitting element may include a 3-1 end relatively close to the second end and a 3-2 end relatively far from the second end.

In the display panel according to the embodiment, the 1-1 end and the 1-2 end may be disposed to face each other, the 2-1 end and the 2-2 end may be disposed to face each other, and the 3-1 end and the 3-2 end may be disposed to face each other.

In the display panel according to the embodiment, a distance between the 1-2 end and the 2-1 end may be less than a distance between the 2-2 end and the 3-1 end.

In the display panel according to the embodiment, a distance between the 1-1 end and the 2-2 end may be greater than a distance between the 2-1 end and the 3-2 end.

In the display panel according to the embodiment, a distance between the first end and the 2-2 end may be substantially the same as a distance between the second end and the 3-1 end.

In the display panel according to the embodiment, a distance between the center of the 1-1 end and the 1-2 end and the center of the 2-1 end and the 2-2 end may be substantially the same as a distance between the center of the 2-1 end and the 2-2 end and the center of the 3-1 end and the 3-2 end.

In the display panel according to the embodiment, the first light-emitting element, the second light-emitting element, and the third light-emitting element may all be inorganic light-emitting elements.

A display device according to an embodiment of the present specification may include a display panel having a plurality of pixels, and a bending area disposed in a first direction from the display panel, wherein each of the plurality of pixels may include a plurality of light-emitting elements, the plurality of light-emitting elements may include a plurality of first light-emitting elements each having a first size and implementing a first color, a plurality of second light-emitting elements each having a second size different from the first size and implementing a second color, and a plurality of third light-emitting elements each having a third size different from the first size and implementing a third color, and the display panel may include a first trench disposed between the second light-emitting elements and the third light-emitting elements and a second trench disposed between the plurality of light-emitting elements.

In the display device according to the embodiment, the first trench may be disposed to extend in the first direction, and the second trench may be disposed to extend in a second direction intersecting the first direction.

In the display device according to the embodiment, the first trench may include a 1-4 trench and a 1-3 trench disposed to be offset from the 1-4 trench in the first direction.

In the display device according to the embodiment, the display panel may include a third trench disposed between the display panel and the bending area.

In the display device according to the embodiment, the third trench may be disposed to extend in a second direction intersecting the first direction.

According to the present specification, the reliability of a display device can be improved by protecting the display device from moisture penetration from the outside.

A lifespan of a display device can be extended by preventing or suppressing moisture penetration from the outside. Accordingly, long-term power consumption can be reduced, and low-power operation can be achieved.

According to the present specification, a loss of (missing) light-emitting elements can be prevented or reduced in a process of forming trenches after a transfer process is completed.

According to the present specification, a design margin of a display device can be secured.

The effects of the present specification are not limited to the effects mentioned above, and other effects not mentioned can be clearly understood by those skilled in the art to which the technical idea of the present specification pertains from the above description.

While various example embodiments of the present disclosure have been described in detail above with reference to the accompanying drawings, the present disclosure is not necessarily limited to these embodiments, and various changes and modifications may be made without departing from the technical spirit of the present disclosure.

Accordingly, the example embodiments disclosed herein are to be considered descriptive and not restrictive of the technical spirit of the present disclosure, and the scope of the technical spirit of the present disclosure is not limited by these embodiments.

Accordingly, the above-described embodiments should be understood to be examples and not limiting in any aspect.

The protected scope of the present disclosure may be construed based on the appended claims, and all technical ideas within the scope of these claims their equivalents should be construed as being included in the scope of the present disclosure.

What is claimed is:

1. A display panel, comprising:
a first light-emitting element having a first size and implementing a first color;
a second light-emitting element having a second size different from the first size and implementing a second color;
a third light-emitting element having a third size different from the first size and implementing a third color; and
a trench formed between the second light-emitting element and the third light-emitting element.

2. The display panel of claim 1, wherein the second size and the third size are substantially the same.

3. The display panel of claim 1, wherein the first size is greater than each of the second size and the third size.

4. The display panel of claim 1, wherein:
the trench includes a first end and a second end facing each other,
the first light-emitting element includes a 1-1 end relatively far from the first end and a 1-2 end relatively close to the first end,
the second light-emitting element includes a 2-1 end relatively far from the first end and a 2-2 end relatively close to the first end, and
the third light-emitting element includes a 3-1 end relatively close to the second end and a 3-2 end relatively far from the second end.

5. The display panel of claim 4, wherein:
the 1-1 end and the 1-2 end are disposed to face each other,
the 2-1 end and the 2-2 end are disposed to face each other, and
the 3-1 end and the 3-2 end are disposed to face each other.

6. The display panel of claim 4, wherein a distance between the 1-2 end and the 2-1 end is less than a distance between the 2-2 end and the 3-1 end.

7. The display panel of claim 4, wherein a distance between the 1-1 end and the 2-2 end is greater than a distance between the 2-1 end and the 3-2 end.

8. The display panel of claim 4, wherein a distance between the first end and the 2-2 end is substantially the same as a distance between the second end and the 3-1 end.

9. The display panel of claim 4, wherein a distance between a center of the 1-1 end and the 1-2 end and a center of the 2-1 end and the 2-2 end is substantially the same as a distance between the center of the 2-1 end and the 2-2 end and a center of the 3-1 end and the 3-2 end.

10. The display panel of claim 1, wherein the first light-emitting element, the second light-emitting element, and the third light-emitting element are all inorganic light-emitting elements.

11. The display panel of claim 4, further comprising a plurality of banks,
wherein each of the first, second and third light-emitting elements is disposed on a corresponding bank among the plurality of banks, and
wherein a distance between the first end and the second end is greater than a distance from the first end to one end of the bank on which a corresponding light-emitting element is disposed, and is less than a distance from one end to the other end of the bank on which a corresponding light-emitting element is disposed.

12. The display panel of claim 4, wherein a distance between the first end and the second end is less than each of a distance between the 2-1 end and the 2-2 end and a distance between the 3-1 end and the 3-2 end.

13. The display panel of claim 4, wherein a distance between the first end and the 2-2 end and a distance between the second end and the 3-1 end each is greater than each of a distance between the 2-1 end and the 2-2 end and a distance between the 3-1 end and the 3-2 end.

14. A display device, comprising:
a display panel having a plurality of pixels; and
a bending area disposed in a first direction from the display panel,
wherein each of the plurality of pixels includes a plurality of light-emitting elements,
wherein the plurality of light-emitting elements include a plurality of first light-emitting elements each having a first size and implementing a first color, a plurality of second light-emitting elements each having a second size different from the first size and implementing a second color, and a plurality of third light-emitting elements each having a third size different from the first size and implementing a third color, and
wherein the display panel includes a first trench disposed between the second light-emitting elements and the third light-emitting elements and a second trench disposed between the plurality of light-emitting elements.

15. The display device of claim 14, wherein:
the first trench is disposed to extend in the first direction, and
the second trench is disposed to extend in a second direction intersecting the first direction.

16. The display device of claim 15, wherein the first trench includes a 1-4 trench and a 1-3 trench disposed to be offset from the 1-4 trench in the first direction.

17. The display device of claim 14, wherein the display panel includes a third trench disposed between the display panel and the bending area.

18. The display device of claim 17, wherein the third trench is disposed to extend in a second direction intersecting the first direction.

19. The display device of claim 14, wherein the second size and the third size are substantially the same.

20. The display device of claim 14, wherein the first size is greater than each of the second size and the third size.
